(19) United States
(12) Patent Application Publication
(10) Pub. No.: US 2022/0056590 A1
(43) Pub. Date: Feb. 24, 2022

(54) SUBSTRATE PROCESSING APPARATUS AND SUBSTRATE PROCESSING METHOD

(71) Applicant: Tokyo Electron Limited, Tokyo (JP)

(72) Inventors: Satoshi Morita, Koshi-shi, Kumamoto (JP); Masami Akimoto, Koshi-shi, Kumamoto (JP); Katsuhiro Morikawa, Koshi-shi, Kumamoto (JP); Kouichi Mizunaga, Koshi-shi, Kumamoto (JP); Mitsuaki Iwashita, Kikuchi-gun, Kumamoto (JP); Satoshi Kaneko, Koshi-shi, Kumamoto (JP)

(21) Appl. No.: 17/279,748

(22) PCT Filed: Sep. 26, 2019
(86) PCT No.: PCT/JP2019/037766

§ 371 Date: Mar. 25, 2021

(30) Foreign Application Priority Data
Sep. 27, 2018 (JP) 2018-182834
Mar. 28, 2019 (JP) 2019-063373

(51) Int. Cl. C23C 18/16; C23C 16/455; H01L 21/02

(52) U.S. Cl. CPC C23C 18/1678; C23C 18/163; H01L 21/02041; C23C 18/168; C23C 16/45563; C23C 18/1642

(57) ABSTRACT

A substrate processing apparatus includes a rotation driving mechanism configured to rotate a rotary table configured to hold a substrate; an electric heater provided in the rotary table to be rotated along with the rotary table and configured to heat the substrate; a power receiving electrode provided in the rotary table to be rotated along with the rotary table and electrically connected to the electric heater; a power feeding electrode configured to be contacted with the power receiving electrode and configured to supply a power to the electric heater via the power receiving electrode; an electrode moving mechanism; a power feeder configured to supply the power to the power feeding electrode; a processing cup surrounding the rotary table; at least one processing liquid nozzle configured to supply a processing liquid; a processing liquid supply mechanism configured to supply at least an electroless plating liquid; and a controller.

### TECHNICAL FIELD

The various aspects and exemplary embodiments described herein pertain generally to a substrate processing apparatus and a substrate processing method.

### BACKGROUND

In the manufacture of a semiconductor device, various liquid processings such as a chemical liquid cleaning processing, a plating processing and a developing processing are performed on a substrate such as a semiconductor wafer. As an apparatus configured to perform such a liquid processing, there is known a single-wafer type liquid processing apparatus, and an example of this single-wafer type liquid processing apparatus is described in Patent Document 1.

The substrate processing apparatus of Patent Document 1 is equipped with a spin chuck capable of holding a substrate horizontally and rotating the substrate around a vertical axis. The substrate is held by a plurality of holding members provided at a peripheral portion of the spin chuck at a regular distance along a circumferential direction thereof. A circular plate-shaped top surface moving member and a circular plate-shaped bottom surface moving member each including a heater embedded therein are respectively disposed above and under the substrate held by the spin chuck. In the substrate processing apparatus of Patent Document 1, processings are performed in the following sequence.

First, the substrate is held by the spin chuck, and by raising the bottom surface moving member, a first gap is formed between a bottom surface (rear surface) of the substrate and a top surface of the bottom surface moving member. Then, a temperature-controlled chemical liquid is supplied into the first gap from a bottom surface supply passage opened at a central portion of the top surface of the bottom surface moving member. Thus, the first gap is filled with the chemical liquid for surface treatment. The chemical liquid is adjusted to have a predetermined temperature by the heater of the bottom surface moving member. Meanwhile, a top surface supply nozzle is located above a top surface (front surface) of the substrate to supply the chemical liquid for surface treatment. Thus, a puddle of the chemical liquid is formed on the top surface of the substrate. Subsequently, the top surface supply nozzle is retreated from above the substrate and the top surface moving member is lowered. Thus, a small second gap is formed between a bottom surface of the top surface moving member and a front surface (top surface) of the puddle of the chemical liquid. The puddle of the chemical liquid is adjusted to have a predetermined temperature by the heater embedded in the top surface moving member. In this state, a chemical liquid processing is performed on the front surface and the rear surface of the substrate while rotating the substrate at a low speed or without rotating the substrate. During the chemical liquid processing, if necessary, the chemical liquid is replenished onto the front surface and the rear surface of the substrate from a chemical liquid supply passage opened at a central portion of the top surface moving member and the above-described bottom surface supply passage.

In the substrate processing apparatus of Patent Document 1, the substrate is heated by a fluid (a processing liquid and/or a gas) interposed between the substrate and the heater.

### PRIOR ART DOCUMENT

Patent Document 1: Japanese Patent Laid-open Publication No. 2002-219424

### DISCLOSURE OF THE INVENTION

### Problems to be Solved by the Invention

In view of the foregoing, the present disclosure provides a technique capable of improving the accuracy of controlling the temperature of the substrate in the substrate processing in which the substrate is plated while the substrate is held on the rotary table.

### Means for Solving the Problems

In one exemplary embodiment, a substrate processing apparatus includes: a rotary table configured to horizontally hold a substrate; a rotation driving mechanism configured to rotate the rotary table around a vertical axis; an electric heater provided in the rotary table to be rotated along with the rotary table and configured to heat the substrate placed on the rotary table; a power receiving electrode provided in the rotary table to be rotated along with the rotary table and electrically connected to the electric heater; a power feeding electrode configured to be contacted with the power receiving electrode and configured to supply a driving power to the electric heater via the power receiving electrode; an electrode moving mechanism configured to allow the power feeding electrode and the power receiving electrode to be relatively contacted with and separated from each other; a power feeder configured to supply the driving power to the power feeding electrode; a processing cup provided to surround the rotary table and connected to an exhaust line and a drain line; at least one processing liquid nozzle configured to supply a processing liquid onto the substrate; a processing liquid supply mechanism configured to supply at least an electroless plating liquid as the processing liquid into the at least one processing liquid nozzle; and a controller configured to control the electrode moving mechanism, the power feeder, the rotation driving mechanism and the processing liquid supply mechanism.

### Effect of the Invention

According to the present disclosure, it is possible to improve the accuracy of controlling the temperature of the substrate in the substrate processing in which the substrate is plated while the substrate is held on the rotary table.

### BRIEF DESCRIPTION OF THE DRAWINGS

FIG. 1 is a plan view illustrating an outline of a substrate processing apparatus according to an exemplary embodiment.

FIG. 2 is a schematic cross sectional view illustrating an example configuration of a processing unit provided in the substrate processing apparatus of FIG. 1.

FIG. 3 is a schematic plan view illustrating an example layout of a heater of a hot plate provided in the processing unit.

FIG. 4 is a schematic plan view illustrating a top surface of the hot plate.

FIG. 5 is a schematic plan view illustrating an example structure of a bottom surface of an attraction plate provided in the processing unit.

FIG. 6 is a schematic plan view illustrating an example structure of a top surface of the attraction plate.

FIG. 7 is a schematic plan view illustrating an example structure of a first electrode unit provided in the processing unit.

FIG. 8 is a time chart for describing example operations of various constituent components of the processing unit.

FIG. 9 is a schematic cross sectional view illustrating the attraction plate shown in FIG. 5 and FIG. 6.

FIG. 10 is a schematic cross sectional view illustrating the attraction plate taken along a different cross section from FIG. 9.

FIG. 11 is a schematic diagram illustrating a curved attraction plate.

FIG. 12 is a schematic plan view illustrating a modification example of the attraction plate.

FIG. 13 is a schematic cross sectional view illustrating another example configuration of the processing unit provided in the substrate processing apparatus.

FIG. 14A is a schematic diagram for describing a principle of a first configuration example of a power transmission mechanism for power feed to an auxiliary heater provided in the processing unit shown in FIG. 13.

FIG. 14B is an axial cross sectional view illustrating a first configuration example of the power transmission mechanism for power feed to the auxiliary heater provided in the processing unit represented as a second liquid processing unit.

FIG. 14C is an axial cross sectional view illustrating a second configuration example of the power transmission mechanism for power feed to the auxiliary heater provided in the processing unit represented as the second liquid processing unit.

FIG. 15 is a block diagram illustrating an example relationship between components involved in temperature control by the heater.

FIG. 16 is a block diagram illustrating another example relationship between components involved in temperature control by the heater.

FIG. 17 is a schematic diagram illustrating an exemplary embodiment further including a top plate.

FIGS. 18A to 18D are schematic diagrams illustrating a plating processing using a processing unit.

### DETAILED DESCRIPTION

Hereinafter, a substrate processing apparatus (substrate processing system) according to an exemplary embodiment will be described with reference to the accompanying drawings.

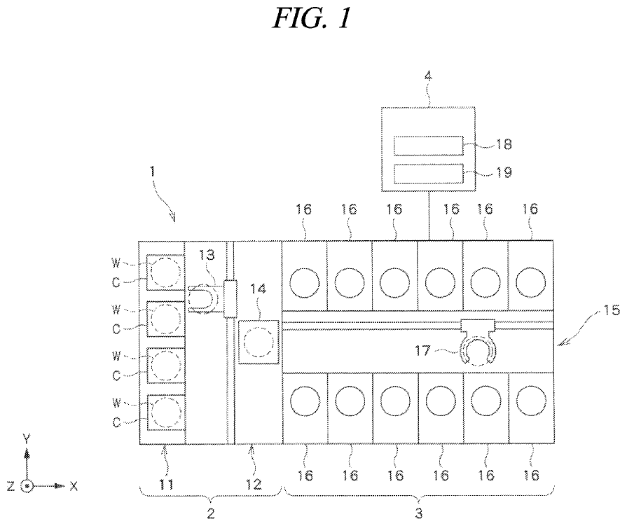

FIG. 1 is a plan view schematic illustrating an outline of a substrate processing system according to an exemplary embodiment. In the following, in order to clarify positional relationships, the X-axis, the Y-axis and the Z-axis which are orthogonal to each other will be defined. The positive Z-axis direction will be regarded as a vertically upward direction.

As shown in FIG. 1, a substrate processing system 1 includes a carry-in/out station 2 and a processing station 3. The carry-in/out station 2 and the processing station 3 are provided adjacent to each other.

The carry-in/out station 2 is equipped with a carrier placing section 11 and a transfer section 12. In the carrier placing section 11, a plurality of carriers C is placed to horizontally accommodate a plurality of substrates, i.e., semiconductor wafers W (hereinafter, referred to as “wafers W”) in the present exemplary embodiment.

The transfer section 12 is provided adjacent to the carrier placing section 11 and equipped with a substrate transfer device 13 and a delivery unit 14. The substrate transfer device 13 is equipped with a wafer holding mechanism configured to hold the wafer W. Further, the substrate transfer device 13 is movable horizontally and vertically and pivotable around a vertical axis and transfers the wafers W between the carriers C and the delivery unit 14 by using the wafer holding mechanism.

The processing station 3 is provided adjacent to the transfer section 12. The processing station 3 is equipped with a transfer section 15 and a plurality of processing units 16. The plurality of processing units 16 is arranged at both sides of the transfer section 15.

The transfer section 15 is equipped with a substrate transfer device 17 therein. The substrate transfer device 17 is equipped with a wafer holding mechanism configured to hold the wafer W. Further, the substrate transfer device 17 is movable horizontally and vertically and pivotable around a vertical axis. The substrate transfer device 17 transfers the wafers W between the delivery unit 14 and the processing units 16 by using the wafer holding mechanism.

The processing units 16 perform a predetermined substrate processing on the wafers W transferred by the substrate transfer device 17.

Further, the substrate processing system 1 is equipped with a control device 4. The control device 4 is, for example, a computer and includes a controller 18 and a storage 19. The storage 19 stores therein a program that controls various processings performed in the substrate processing system 1. The controller 18 controls the operations of the substrate processing system 1 by reading and executing the program stored in the storage 19.

Further, the program may be recorded in a computer-readable recording medium and may be installed from the recording medium to the storage 19 of the control device 4. The computer-readable recording medium may be, for example, a hard disk (HD), a flexible disk (FD), a compact disk (CD), a magneto optical disc (MO), a memory card, or the like.

In the substrate processing system 1 configured as described above, the substrate transfer device 13 of the carry-in/out station 2 first takes out the wafer W from the carrier C placed in the carrier placing section 11 and then places the taken wafer W on the delivery unit 14. The wafer W placed on the delivery unit 14 is taken out from the delivery unit 14 by the substrate transfer device 17 of the processing station 3 and carried into the processing unit 16.

The wafer W carried into the processing unit 16 is processed by the processing unit 16, and then carried out from the processing unit 16 and placed on the delivery unit 14 by the substrate transfer device 17. After the processing of placing the wafer W on the delivery unit 14, the wafer W returns back to the carrier C of the carrier placing section 11 by the substrate transfer device 13.

Hereinafter, the configuration of the processing unit 16 according to the exemplary embodiment will be described. The processing unit 16 is configured as a single-wafer type dip liquid processing unit.

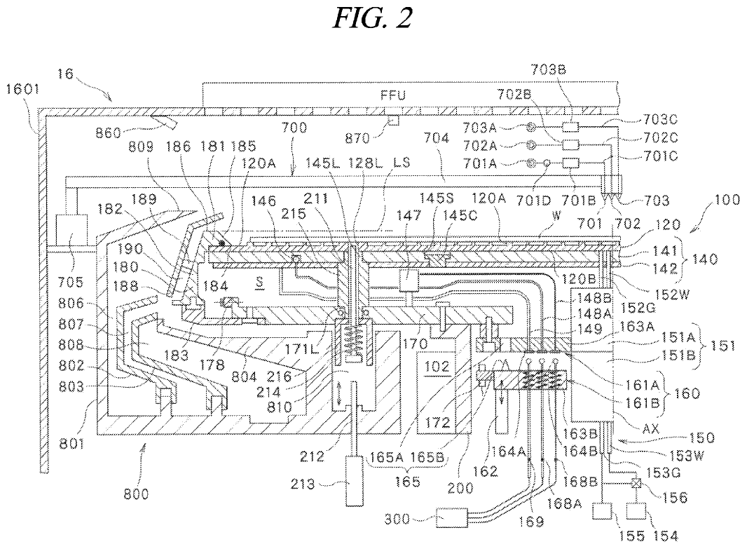

As shown in FIG. 2, the processing unit 16 is equipped with a rotary table 100, a processing liquid supply 700 configured to supply a processing liquid onto the wafer W and a liquid recovery cup (processing cup) 800 configured to receive the processing liquid scattered from the substrate being rotated. The rotary table 100 is capable of horizontally holding and rotating a circular substrate such as a wafer W. The constituent components of the processing unit 16, such as the rotary table 100, the processing liquid supply 700 and the liquid recovery cup 800, are accommodated in a housing 1601 (also referred to as “processing chamber”). FIG. 2 illustrates only a left half of the processing unit 16.

The rotary table 100 includes an attraction plate 120, a hot plate 140, a support plate 170, a periphery cover body 180 and a hollow rotation shaft 200. The attraction plate 120 is configured to horizontally attract the wafer W placed thereon. The hot plate 140 serves as a base plate of the attraction plate 120 and is configured to support and heat the attraction plate 120. The support plate 170 is configured to support the attraction plate 120 and the hot plate 140. The rotation shaft 200 extends downwards from the support plate 170. The rotary table 100 is rotated around a vertically extending rotation axis Ax by an electric driving unit (rotation driving mechanism) 102 disposed around the rotation shaft 200. Thus, the wafer W held by the rotary table 100 can be rotated around the rotation axis Ax. The electric driving unit 102 (details of which are not illustrated) is configured to transfer a motive power generated by an electric motor to the rotation shaft 200 via a power transmission mechanism (for example, a belt and a pulley) to rotate the rotation shaft 200. Alternatively, the electric driving unit 102 may be configured to rotate the rotation shaft 200 directly by the electric motor.

The attraction plate 120 is a circular plate-shaped member having a slightly larger diameter than the wafer W (or the same diameter as that of the wafer W in some configurations), i.e., circular plate-shaped member having the same or larger area than the wafer W. The attraction plate 120 has a top surface (front surface) 120A configured to attract a bottom surface (not to be processed) of the wafer W and a bottom surface (rear surface) 120B in contact with a top surface of the hot plate 140. The attraction plate 120 may be made of a material having high thermal conductivity such as thermal conductive ceramic, for example, SiC. Desirably, the material of the attraction plate 120 may have a thermal conductivity of 150 W/m·k or more.

The hot plate 140 is a circular plate-shaped member having substantially the same diameter as that of the attraction plate 120. The hot plate 140 has a plate main body 141 and an electric heater 142 provided in the plate main body 141. The plate main body 141 is made of a material having high thermal conductivity such as thermal conductive ceramic, for example, SiC. Desirably, the material of the plate main body 141 may have a thermal conductivity of 150 W/m·k or more.

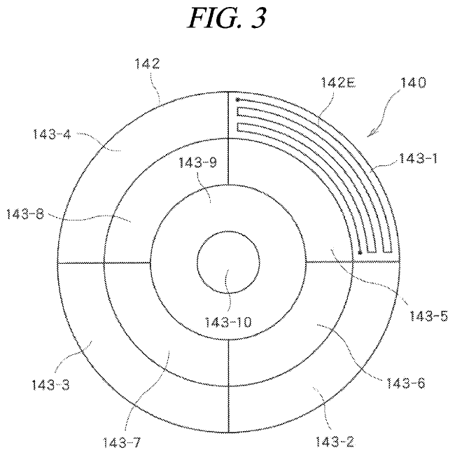

The heater 142 may be configured as a sheet-type heater, e.g., a polyimide heater, provided in a bottom surface (rear surface) of the plate main body 141. Desirably, a plurality of (for example, ten) heating zones 143-1 to 143-10 is set in the hot plate 140, as shown in FIG. 3. The heater 142 is composed of a plurality of heater elements 142E respectively assigned to the heating zones 143-1 to 143-10. Each heater element 142E is made of a conductor extending in a zigzag shape within each of the heating zones 143-1 to 143-10. FIG. 3 illustrates only the heater element 142E within the heating zone 143-1.

An electric power can be fed to the plurality of heater elements 142E independently by a power feeder 300 to be described later. Accordingly, the different heating zones for the wafer W can be heated in different conditions, and, thus, it is possible to control the temperature distribution of the wafer W.

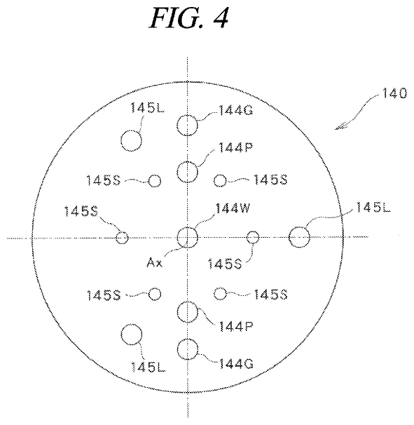

As shown in FIG. 4, a top surface (front surface) of the plate main body 141 has one or more (two in the illustrated exemplary embodiment) plate suction holes 144P, one or more (one at a central portion in the illustrated exemplary embodiment) substrate suction hole 144W and one or more (two at an outer portion in the illustrated exemplary embodiment) purge gas supply holes 144G. The plate suction holes 144P are used to transfer a suction force for attracting the attraction plate 120 to the hot plate 140. The substrate suction hole 144W is used to transfer a suction force for attracting the wafer W to the attraction plate 120.

Further, the plate main body 141 is equipped with a plurality of (three in the illustrated exemplary embodiment) lift pin holes 145L through which lift pins 211 to be described later pass and a plurality of (six in the illustrated exemplary embodiment) service holes 145S for accessing assembly screws of the rotary table 100. During a normal operation, the service holes 145S are closed with caps 145C.

The above-described heater elements 142E are arranged to avoid the plate suction holes 144P, the substrate suction hole 144W, the purge gas supply holes 144G, the lift pin holes 145L and the service holes 145S. Further, by achieving the connection to the rotation shaft 200 through an electromagnet, the service holes may be omitted.

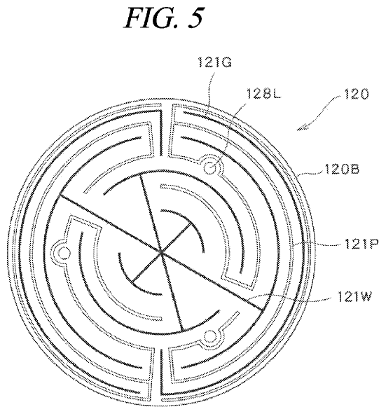

As shown in FIG. 5, the bottom surface 120B of the attraction plate 120 has a plate bottom surface suction path groove 121P, a substrate bottom surface suction path groove 121W and a bottom surface purge path groove 121G. When the attraction plate 120 is placed in an appropriate positional relationship on the hot plate 140, at least a part of the plate bottom surface suction path groove 121P communicates with the plate suction holes 144P. Likewise, at least a part of the substrate bottom surface suction path groove 121W communicates with the substrate suction hole 144W, and at least a part of the bottom surface purge path groove 121G communicates with the purge gas supply holes 144G. The plate bottom surface suction path groove 121P, the substrate bottom surface suction path groove 122W and the bottom surface purge path groove 121G are arranged separately from each other (do not communicate with each other).

FIG. 10 schematically illustrates a state where the suction holes 144P (or 144W or 144G) of the hot plate 140 and the path groove 121P (or 121W or 121G) of the attraction plate 120 are overlapped to communicate with each other.

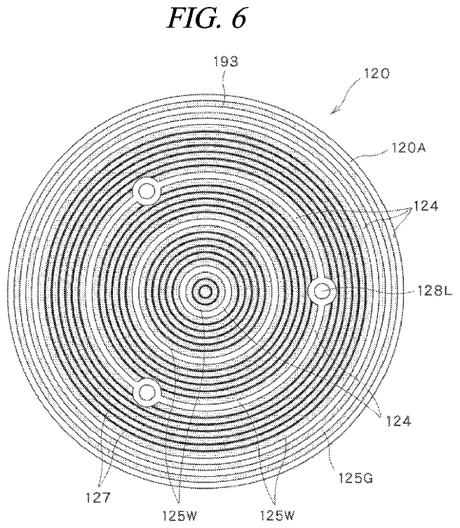

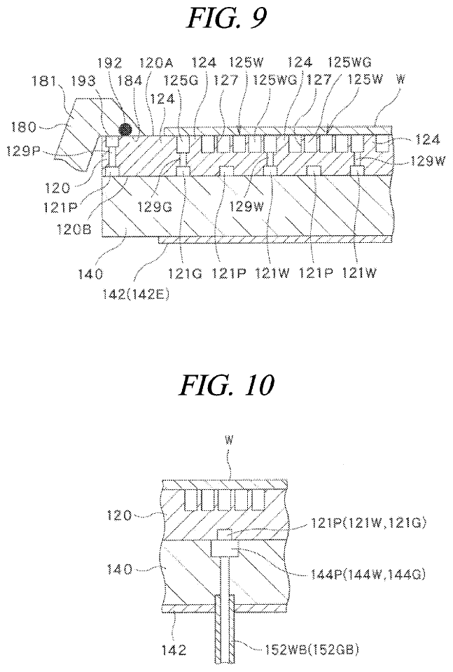

As shown in FIG. 6 and FIG. 9, a plurality of (five in the illustrated exemplary embodiment) thick annular partition walls 124 is formed on the top surface 120A of the attraction plate 120. The thick partition walls 124 define, on the top surface 120A, a plurality of recess regions 125W and 125G (four circular ring-shaped regions in an outer portion and a circular region in an innermost portion) which is separated from each other.

A plurality of through holes 129G penetrating the attraction plate 120 in a thickness direction thereof is formed at a plurality of locations on the substrate bottom surface suction path groove 121W, and each through hole allows the substrate bottom surface suction path groove 121W to communicate with the corresponding one of the plurality of (four in the illustrated exemplary embodiment) recess regions 125W.

Further, through holes 129G penetrating the attraction plate 120 in the thickness direction are formed at a plurality of locations on the bottom surface purge path groove 121G, and each through hole allows the bottom surface purge path groove 121G to communicate with the outermost recess region 125G. The outermost recess region 125G serves as a single top surface purge path groove having a circular ring shape.

In each of the four recess regions 125W in the inner portion, a plurality of thin annular separation walls 127 is provided concentrically. The narrow separation walls 127 form at least one top surface suction path groove 125WG extending in a zigzag shape within each recess region 125W. That is, the narrow separation walls 127 serve to uniformly distribute the suction force within each recess region 125W.

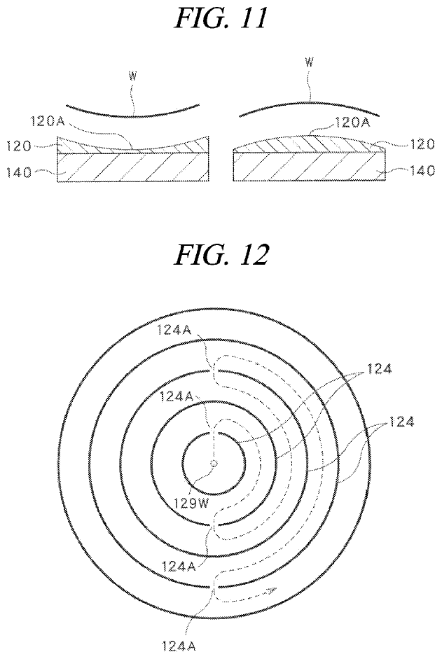

The top surface 120A of the attraction plate 120 may be flat overall. The top surface 120A of the attraction plate 120 may be curved overall as schematically shown in FIG. 11. It is known that a wafer W is curved in a certain direction depending on a structure and an arrangement of devices formed on the surface of the wafer W. By using the attraction plate 120 whose top surface 120A is curved to conform to the curvature of the wafer W, the wafer W can be securely attracted.

In the exemplary embodiment shown in FIG. 6, the plurality of recess regions 125W isolated from each other by the partition walls 124 is formed, but the present disclosure is not limited thereto. For example, as schematically shown in FIG. 12, the partition walls 124 may have communication paths 124A through which recess regions corresponding to the recess regions 125W of FIG. 6 are allowed to communicate with each other. In this case, only one through hole 129W may be formed, for example, at a central portion of the attraction plate 120. Further, without the thick partition walls 124, only a plurality of narrow separation walls corresponding to the separation walls 127 of FIG. 6 may be provided to have the same structure as that of the partition walls 124 of FIG. 12.

As shown in FIG. 2, a suction/purge unit 150 is provided in the vicinity of the rotation axis Ax. The suction/purge unit 150 is equipped with a rotary joint 151 provided within the hollow rotation shaft 200. An upper piece 151A of the rotary joint 151 is connected to a suction line 152W communicating with the plate suction holes 144P and the substrate suction hole 144W of the hot plate 140 and a purge gas supply line 152G communicating with the purge gas supply holes 144G.

Although not shown in the drawings, the suction line 152W may be branched into a branch suction line and this branch suction line may be connected to the plate main body 141 of the hot plate 140 directly under the plate suction holes 144P and the substrate suction hole 144W. In this case, vertically extending through holes may be formed through the plate main body 141 and the branch suction line may be connected to each through hole. Likewise, the purge gas supply line 152G may be branched into a branch purge gas supply line and this branch purge gas supply line may be connected to the plate main body 141 of the hot plate 140 directly under the purge gas supply holes 144G. In this case, vertically extending through holes may be formed through the plate main body 141 and the purge gas supply line may be connected to each through hole. The above-described branch suction line and the branch purge gas line are schematically shown in FIG. 10 (denoted by reference numerals 152WB and 152GB, respectively).

Alternatively, the suction line 152W and the purge gas supply line 152G may be connected to a central portion of the plate main body 141 of the hot plate 140. In this case, a path through which the suction line 152W is allowed to communicate with the plate suction holes 144P and the substrate suction hole 144W and a path through which the purge gas supply line 152G is allowed to communicate with the purge gas supply holes 144G are provided within the plate main body 141.

A lower piece 151B of the rotary joint 151 is connected to a suction line 153W communicating with the suction line 152W and a purge gas supply line 153G communicating with the purge gas supply line 151G. The rotary joint 151 is configured such that the upper piece 151A and the lower piece 151B can be rotated relative to each other while the suction lines 152W and 153W are kept in communication each other and the purge gas supply lines 152G and 153G are kept in communication each other. The rotary joint 151 having this function has been well known in the art.

The suction line 153W is connected to a suction device 154 such as a vacuum pump. The purge gas supply line 153G is connected to a purge gas supply device 155. The suction line 153W is also connected to the purge gas supply device 155. Further, a switch device (for example, three-way valve) 156 configured to switch a connection destination of the suction line 153W between the suction device 154 and the purge gas supply device 155 is provided.

A plurality of temperature sensors 146 configured to detect the temperature of the plate main body 141 of the hot plate 140 is embedded in the hot plate 140. For example, the temperature sensors 146 may be provided for the ten heating zones 143-1 to 143-10 in one-to-one correspondence. Further, at least one thermo switch 147 configured to detect overheating of the heater 142 is provided near the heater 142 of the hot plate 140.

Besides the temperature sensors 146 and the thermo switch 147, control signal lines 148A and 148B for transmitting detection signals of the temperature sensors 146 and the thermo switch 147 and a power feed line 149 for power feed to each heater element 142E of the heater 142 are provided in a space S between the hot plate 140 and the support plate 170.

As shown in FIG. 2, a switch mechanism 160 is provided near the rotary joint 151. The switch mechanism 160 is equipped with a first electrode unit 161A fixed with respect to the direction of the rotation axis Ax, a second electrode unit 161B configured to be movable in the direction of the rotation axis Ax and an electrode moving mechanism 162 (elevating mechanism) configured to move (elevate) the second electrode unit 161B in the direction of the rotation axis Ax.

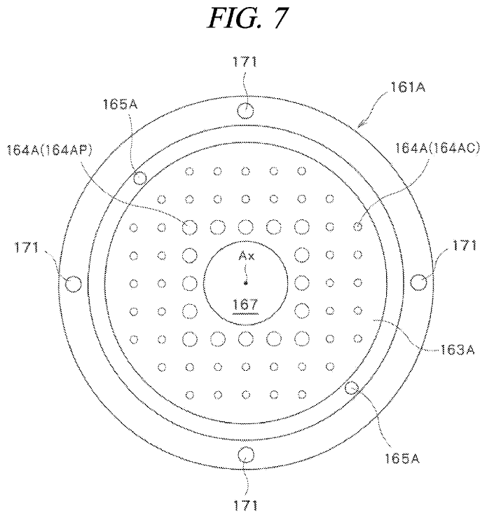

As shown in FIG. 7, the first electrode unit 161A is equipped with a first electrode supporting body 163A and a plurality of first electrodes 164A supported by the first electrode supporting body 163A. The plurality of first electrodes 164A includes first electrodes 164AC (indicated by small “O” in FIG. 7) for control signal communication connected to the control signal lines 148A and 148B and first electrodes 164AP (indicated by large “O” in FIG. 7) for heater power feed connected to the power feed line 149. Desirably, the first electrode 164AP in which a high current (heater current) flows is set to have a larger area than the first electrode 164AC in which a low current (control signal current) flows.

The first electrode supporting body 163A is a member having a circular plate shape overall. A circular hole 167 into which the upper piece 151A of the rotary joint 151 is inserted is formed at a central portion of the first electrode supporting body 163A. The upper piece 151A of the rotary joint 151 may be fixed to the first electrode supporting body 163A. A peripheral portion of the first electrode supporting body 163A may be screw-coupled to the support plate 170 by using screw holes 171.

As schematically shown in FIG. 2, the second electrode unit 161B is equipped with a second electrode supporting body 163B and a plurality of second electrodes 164B supported by the second electrode supporting body 163B. The second electrode supporting body 163B is a member having a circular plate shape overall and having substantially the same diameter as that of the first electrode supporting body 163A shown in FIG. 7. A circular hole through which the lower piece 151B of the rotary joint 151 can pass is formed at a central portion of the second electrode supporting body 163B.

The second electrodes 164B configured to be contacted or separated with respect to the first electrodes 164A by being moved up and down with respect to the first electrodes 164A have the same layout as that of the first electrodes 164A. Hereinafter, the second electrodes 164B (power feeding electrodes) configured to be brought into contact with the first electrodes 164AP (power receiving electrodes) for heater power feed will also be referred to as “second electrodes 164BP”. Further, the second electrodes 164B configured to be brought into contact with the first electrodes 164AC for control signal communication will also be referred to as “second electrodes 164BC”. The second electrodes 164BP are connected to a power output port of the power feed device (power feeder) 300. The second electrodes 164BC are connected to a control input/output port of the power feeder 300.

At least a part of conductive paths (conductive lines) 168A, 168B and 169 (see FIG. 2) connecting the second electrodes 164B to the power output port and the control input/output port of the power feeder 300 is made of a flexible wire. Due to the flexible wire, the entire second electrode unit 161B can be rotated around the rotation axis Ax in a forward rotation direction and in a backward rotation direction from a neutral position at a predetermined angle while maintaining the electric conduction between the second electrodes 164B and the power feeder 300. The predetermined angle may be, for example, 180 degrees, but is not limited thereto. This means that the rotary table 100 can be rotated by about ±180 degrees while maintaining the contact between the first electrodes 164A and the second electrodes 164B.

One of the first electrode 164A and the second electrode 164B in each pair may be configured as a pogo pin. In FIG. 2, all the second electrodes 164B are configured as pogo pins. Here, the term “pogo pin” is widely used to imply an extensible/contractible rod-shaped electrode having a spring embedded therein. Instead of the pogo pin, a socket, a magnet electrode, an induction electrode, or the like may be used as the electrode.

Desirably, there may be provided a lock mechanism 165 configured to lock the first electrode supporting body 163A and the second electrode supporting body 163B not to be rotated relative to each other when the first electrode 164A and the second electrode 164B are in appropriate contact with each other. For example, as shown in FIG. 2, the lock mechanism 165 may be composed of a hole 165A formed at the first electrode supporting body 163A and a pin 165B provided at the second electrode supporting body and configured to be inserted and fitted into the hole.

Desirably, there may also be provided a device 172 (schematically shown in FIG. 2) configured to detect an appropriate contact between the first electrode 164A and the second electrode 164B. This device 172 may be an angular position sensor (not shown) configured to detect a state where the first electrode supporting body 163A and the second electrode supporting body 163B have an appropriate angular positional relationship. Alternatively, this device 172 may be a distance sensor (not shown) configured to detect a state where the first electrode supporting body 163A and the second electrode supporting body 163B have an appropriate distance in the direction of the rotation axis Ax. Still alternatively, this device 172 may be a contact type sensor (not shown) configured to detect a state where the pin 165B is appropriately inserted and fitted into the hole 165A of the lock mechanism 165.

The electrode moving mechanism 162 schematically shown in FIG. 2 may be equipped with, although not shown, a push rod configured to push the second electrode supporting body 163B upwards and an elevating mechanism (an air cylinder, a ball screw, or the like) configured to move the push rod up and down (first configuration example). For example, when using this configuration, a permanent magnet may be provided at the first electrode supporting body 163A and an electromagnet may be provided at the second electrode supporting body 163B. With this configuration, when necessary, the first electrode unit 161A and the second electrode unit 161B can be coupled not to be vertically moved relative to each other, and the first electrode unit 161A and the second electrode unit 161B can be separated from each other.

When adopting the first configuration example, if the first electrode unit 161A and the second electrode unit 161B are contacted and separated at the same angular position of the rotary table 100, the second electrode unit 161B does not need to be supported to be rotatable around the rotation axis Ax. That is, only a member (for example, the above-described push rod, or another supporting table) configured to support the second electrode unit 161B when the first electrode unit 161A and the second electrode unit 161B are separated from each other may be needed.

Instead of the above-described first configuration example, a second configuration example may be adopted. Although not shown in detail in the drawings, the second configuration example of the electrode moving mechanism 162 is equipped with a first ring-shaped member having a circular ring shape centered on the rotation axis Ax, a second ring-shaped member configured to support the first ring-shaped member, a bearing provided between the first and second ring-shaped members and configured to enable the first and second ring-shaped members to be rotated relative to each other, and an elevating mechanism (an air cylinder, a ball screw, or the like) configured to move the second ring-shaped member up and down.

When adopting any one of the first configuration example and the second configuration example, it is possible to rotate the first electrode unit 161A and the second electrode unit 161B together within a limited range while keeping the first electrode 164A and the second electrode 164B in the appropriate contact with each other.

The electric driving unit 102 of the rotary table 100 has a positioning function to stop the rotary table 100 at a certain rotational angular position. This positioning function can be implemented by rotating a motor of the electric driving unit 102 based on a detection value of a rotary encoder provided in the rotary table 100 (or a member rotated by the rotary table 100). By moving the second electrode unit 161B upwards with the electrode moving mechanism 162 in a state where the rotary table 100 is stopped at a predetermined rotational angular position, corresponding electrodes of the first electrode unit 161A and the second electrode unit 161B can be brought into appropriate contact with each other. Desirably, the second electrode unit 161B may be separated from the first electrode unit 161A in the state where the rotary table 100 is stopped at the predetermined rotational angular position.

As described above, a plurality of electronic components (heater, wiring, sensor) are disposed in the space S between the attraction plate 120 and the support plate 170 and at positions facing the space S. The periphery cover body 180 suppresses a processing liquid supplied to the wafer W, particularly, a corrosive chemical liquid from being introduced into the space S and thus protects the electronic components. A purge gas (N₂ gas) may be supplied into the space S through a line (not shown) branched from the purge gas supply line 152G. By supplying the purge gas into the space S in this way, the introduction of a corrosive gas originated from the chemical liquid into the space S from the outside can be suppressed, and, thus, the space S can be maintained in a non-corrosive atmosphere.

As shown in FIG. 2, the periphery cover body 180 has an upper portion 181, a side peripheral portion 182 and a lower portion 183. The upper portion 181 is protruded above the attraction plate 120 and connected to the attraction plate 120. The lower portion 183 of the periphery cover body 180 is coupled to the support plate 170.

An inner periphery of the upper portion 181 of the periphery cover body 180 is located at an inner side in a radial direction than an outer periphery of the attraction plate 120. The upper portion 181 has a circular ring-shaped bottom surface 184 in contact with the top surface of the attraction plate 120, an inclined circular ring-shaped inner peripheral surface 185 starting from an inner periphery of the bottom surface 184, and a circular ring-shaped outer peripheral surface 186 extending outwards substantially horizontally in the radial direction from an outer periphery of the inner peripheral surface 185. The inner peripheral surface 185 is inclined to be lowered as it approaches the central portion of the attraction plate 120.

Desirably, a seal is provided between the top surface 120A of the attraction plate 120 and the bottom surface 184 of the upper portion 181 of the periphery cover body 180 to suppress introduction of the liquid. The seal may be an O-ring 192 disposed between the top surface 120A and the bottom surface 184.

As shown in FIG. 5, a part of the plate bottom surface suction path groove 121P extends in the circumferential direction at an outermost portion of the attraction plate 120. Further, as shown in FIG. 6, a groove 193 extends continuously in the circumferential direction at an outermost portion of the top surface 120A of the attraction plate 120. As shown in FIG. 9, the plate bottom surface suction path groove 121P at the outermost portion and the groove 193 communicate with each other via a plurality of through holes 129P which is formed through the attraction plate 120 in the thickness direction and arranged at a regular distance in the circumferential direction. The bottom surface 184 of the upper portion 181 of the periphery cover body 180 is placed on the groove 193. Accordingly, the bottom surface 184 of the upper portion 181 of the periphery cover body 180 is attracted to the top surface 120A of the attraction plate 120 by a negative pressure acting on the plate bottom surface suction path groove 121P. Since the O-ring 192 is deformed through this attraction, the secure sealing can be achieved.

As shown in FIG. 2, the height of the outer peripheral surface 186, i.e., a top portion of the periphery cover body 180, is higher than the height of the top surface of the wafer W held by the attraction plate 120. Accordingly, if the processing liquid is supplied onto the top surface of the wafer W in the state that the wafer W is held by the attraction plate 120, a liquid accumulation (puddle), in which the wafer W can be immersed so that the top surface of the wafer W is located under a liquid surface LS, can be formed. That is, the upper portion 181 of the periphery cover body 180 forms a bank surrounding the wafer W held by the attraction plate 120. A recess portion in which the processing liquid can be stored is defined by this bank and the attraction plate 120.

The inclination of the inner peripheral surface 185 of the upper portion 181 of the periphery cover body 180 facilitates outward scattering of the processing liquid within the above-described recess portion when the rotary table 100 is rotated at a high speed. That is, this inclination suppresses the liquid from staying on the inner peripheral surface of the upper portion 181 of the periphery cover body 180 when the rotary table 100 is rotated at a high speed.

A rotary cup 188 (rotary liquid recovery member) configured to be rotated along with the periphery cover body 180 is provided outside the periphery cover body 180 in the radial direction. The rotary cup 188 is connected to a constituent component of the rotary table 100, i.e., the periphery cover body 180 in the illustrated exemplary embodiment, via a plurality of connecting members 189 arranged at a regular distance in the circumferential direction. An upper end of the rotary cup 188 is located at a height where the processing liquid scattered from the wafer W can be received. A passageway 190 through which the processing liquid scattered from the wafer W flows down is formed between an outer peripheral surface of the side peripheral portion 182 of the periphery cover body 180 and an inner peripheral surface of the rotary cup 188.

The liquid recovery cup 800 surrounds the rotary table 100 and is configured to collect the processing liquid scattered from the wafer W. In the illustrated exemplary embodiment, the liquid recovery cup 800 is equipped with a stationary outer cup component 801, a stationary inner cup component 804, a first movable cup component 802, a second movable cup component 803 configured to be movable up and down and a stationary inner cup component 804. Each of a first discharge passageway 806, a second discharge passageway 807 and a third discharge passageway 808 is formed between two adjacent cup components (between 801 and 802, between 802 and 803 and between 803 and 804). By changing the positions of the first and second movable cup components 802 and 803, the processing liquid discharged from the passageway 190 between the periphery cover body 180 and the rotary cup 188 can be guided into any selected one of the three discharge passageways 806 to 808. The first discharge passageway 806, the second discharge passageway 807 and the third discharge passageway 808 are respectively connected to an acidic liquid drain passageway, an alkaline liquid drain passageway and an organic liquid drain passageway (all of which are not illustrated) which are provided in a semiconductor manufacturing factory. A non-illustrated gas-liquid separation structure is provided within each of the first discharge passageway 806, the second discharge passageway 807 and the third discharge passageway 808. The first discharge passageway 806, the second discharge passageway 807 and the third discharge passageway 808 are connected to and suctioned by a factory exhaust system via an exhaust device (not shown) such as an ejector. This liquid recovery cup 800 has been well known in the art by Japanese Patent Laid-open Publication No. 2012-129462, Japanese Patent Laid-open Publication No. 2014-123713, Japanese laid-open publication pertinent to the present patent application filed by the present applicant, and so forth. For details of this liquid recovery cup 800, these documents may be referred to.

Three lift pin holes 128L and three lift pin hoes 171L are formed at the attraction plate 120 and the support plate 170, respectively, so as to be aligned with the three lift pin holes 145L of the hot plate 140 in the direction of the rotation axis Ax.

The rotary table 100 is equipped with a plurality of (three in the illustrated exemplary embodiment) lift pins 211 inserted through the lift pin holes 145L, 128L and 171L. Each of the lift pins 211 can be moved between a delivery position (raised position) where an upper end of the lift pin 211 protrudes above the top surface 120A of the attraction plate 120 and a processing position (lowered position) where the upper end of the lift pin 211 is located under the top surface 120A of the attraction plate 120.

A push rod 212 is provided under each lift pin 211. The push rod 212 can be moved up and down by an elevating mechanism 213, for example, an air cylinder. By pushing lower ends of the lift pins 211 upwards with the push rods 212, the lift pins 211 can be raised to the delivery position. Alternatively, a plurality of push rods 212 may be provided at a ring-shaped supporting body (not shown) centered on the rotation axis Ax and moved up and down by moving the ring-shaped supporting body up and down by a common elevating mechanism.

The wafer W loaded on the lift pins 211 at the delivery position is located at a height position higher than an upper end 809 of the stationary outer cup component 801, and this wafer W can be delivered to/from an arm (see FIG. 1) of the substrate transfer device 17 that has advanced into the processing unit 16.

If the lift pins 211 are apart from the push rods 212, the lift pins 211 are lowered down to the processing position by an elastic force of a return spring 214 and held at the processing position. In FIG. 2, a reference numeral 215 denotes a guide member configured to guide a vertical movement of the lift pin 211 and a reference numeral 216 denotes a spring seat configured to receive the return spring 214. Further, a circular ring-shaped recess 810 is formed at the stationary inner cup component 804 to allow a rotation of the spring seat 216 around the rotation axis Ax.

The processing liquid supply 700 is equipped with a plurality of nozzles. The plurality of nozzles includes a chemical liquid nozzle 701, a rinse nozzle 702 and a drying accelerator liquid nozzle 703. A chemical liquid is supplied into the chemical liquid nozzle 701 from a chemical liquid source 701A via a chemical liquid supply mechanism 701B including a flow control device (not shown) such as an opening/closing valve and a flow rate control valve which are provided at a chemical liquid supply line (pipe) 701C. A rinse liquid is supplied from a rinse liquid source 702A via a rinse liquid supply mechanism 702B including a flow control device (not shown) such as an opening/closing valve and a flow rate control valve which are provided at a rinse liquid supply line (pipe) 702C. A drying accelerator liquid, for example, IPA (isopropyl alcohol) is supplied from a drying accelerator liquid source 703A via a drying accelerator liquid supply mechanism 703B including a flow control device (not shown) such as an opening/closing valve and a flow rate control valve which are provided at a drying accelerator supply line (pipe) 703C.

The chemical liquid supply line 701C may be equipped with a heater 701D as a temperature adjustment mechanism for adjusting the temperature of the chemical liquid. Further, a tape heater (not shown) for adjusting the temperature of the chemical liquid may be provided at a pipe constituting the chemical liquid supply line 701C. Likewise, the rinse liquid supply line 702C may also be equipped with such a heater.

The chemical liquid nozzle 701, the rinse nozzle 702 and the drying accelerator liquid nozzle 703 are supported by a tip end of a nozzle arm 704. A base end of the nozzle arm 704 is supported by a nozzle arm driving mechanism 705 configured to move up and down and rotate the nozzle arm 704. The chemical liquid nozzle 701, the rinse nozzle 702 and the drying accelerator liquid nozzle 703 can be located at a certain position above the wafer W in the radial direction (a position with respect to the radial direction of the wafer W) by the nozzle arm driving mechanism 705.

A wafer sensor 860 configured to detect presence or absence of the wafer W on the rotary table 100, and one or more infrared thermometers 870 (only one is illustrated) configured to detect the temperature of the wafer W (or the temperature of the processing liquid on the wafer W) are disposed at a ceiling of the housing 1601. If a plurality of infrared thermometers 870 is provided, desirably, the infrared thermometers 870 detect the temperatures of regions of the wafer W corresponding to the heating zones 143-1 to 143-10, respectively.

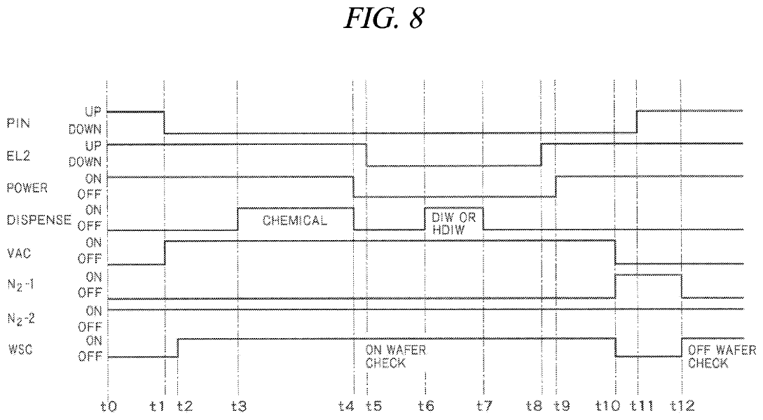

Hereinafter, with reference to a time chart of FIG. 8, an operation of the processing unit 16 will be described for a case where the processing unit 16 performs a chemical liquid cleaning processing. The operation to be described below can be performed under the control of the control device 4 (controller 18) shown in FIG. 1 which controls operations of various constituent components of the processing unit 16.

In the time chart of FIG. 8, the horizontal axis represents a lapse of time. The following items are shown in the vertical axis in sequence from the top.

“PIN” denotes a height position of the lift pin 211. “UP” indicates that the lift pin 211 is located at the delivery position and “DOWN” indicates that the lift pin 211 is located at the processing position.

“EL2” denotes a height position of the second electrode unit 161B. “UP” indicates that the second electrode unit 161B is located at the height position where it is in contact with the first electrode unit 161A and “DOWN” indicates that the second electrode unit 161B is located at the height position apart from the first electrode unit 161A.

“POWER” denotes a state of the power feed to the heater 142 from the power feeder 300. “ON” indicates a state where the power feed is being performed and “OFF” indicates a state where the power feed is stopped.

“VAC” denotes a state of application of a suction force from the suction device 154 to the bottom surface suction path groove 121W of the attraction plate 120. “ON” indicates that the suctioning is being performed and “OFF” indicates that the suctioning is stopped.

“N₂-1” indicates a state of supply of a purge gas from the purge gas supply device 155 into the bottom surface suction path groove 121W of the attraction plate 120. “ON” indicates that the supply of the purge gas is being performed and “OFF” indicates the supply of the purge gas is stopped.

“N₂-2” denotes a state of supply of a purge gas from the purge gas supply device 155 into the bottom surface purge path groove 121G of the attraction plate 120. “ON” indicates that the supply of the purge gas is being performed and “OFF” indicates the supply of the purge gas is stopped.

“WSC” denotes an operational state of the wafer sensor 860. “ON” indicates a state where the wafer sensor 860 is detecting the presence or absence of the wafer W on the attraction plate 120 and “OFF” indicates a state where the wafer sensor 860 does not perform the detection. Further, “On Wafer Check” is a detecting operation for checking whether the wafer W is present on the attraction plate 120. “OFF Wafer Check” is a detecting operation for checking whether the wafer W is completely removed from the attraction plate 120.

[Wafer W Carry-in Process (Holding Process)]

The arm (see FIG. 1) of the substrate transfer device 17 advances into the processing unit 16 and is located directly above the attraction plate 120, and the lift pins 211 are located at the delivery position (times t0 to t1). In this state, the arm of the substrate transfer device 17 is lowered. Accordingly, the wafer W is loaded on the upper ends of the lift pins 211 so as to be apart from the arm. Then, the arm of the substrate transfer device 17 is retreated from the processing unit 16. The lift pins 211 are lowered down to the processing position, and in the meantime, the wafer W is placed on the top surface 120A of the attraction plate 120 (time t1).

Subsequently, as the suction device 154 is operated, the attraction plate 120 is attracted to the hot plate 140 and the wafer W is attracted to the attraction plate 120 (time t1). Thereafter, an inspection is started by the wafer sensor 860 to inspect whether the wafer W is appropriately attracted to the attraction plate 120 (time t2).

The purge gas (e.g., N₂ gas) is constantly supplied to the outermost recess region 125G on the top surface of the attraction plate 120 from the purge gas supply device 155. Accordingly, even if there exists a gap between the contact surfaces of the peripheral portion of the bottom surface of the wafer W and the peripheral portion of the attraction plate 120, the processing liquid is not introduced between the peripheral portion of the wafer W and the peripheral portion of the attraction plate 120 through the gap.

From a time before the carry-in of the wafer W is started (before time t0), the second electrode unit 161B is placed at the raised position and the plurality of first electrodes 164A of the first electrode unit 161A and the plurality of second electrodes 164B of the second electrode unit 161B are in contact with each other. The power is fed to the heater 142 of the hot plate 140 from the power feeder 300, and, thus, the heater 142 of the hot plate 140 is in a pre-heated state.

[Wafer Heating Process]

When the wafer W is attracted to the attraction plate 120, the power to be supplied to the heater 142 of the hot plate 140 is adjusted to allow the temperature of the hot plate 140 to reach a predetermined temperature (a temperature at which the wafer W on the attraction plate 120 can be heated to a temperature suitable for a subsequent processing) (times t1 to t3).

[Chemical Liquid Processing Process (Including Puddle Forming Process and Stirring Process)]

Subsequently, the chemical liquid nozzle 701 is located directly above the central portion of the wafer W by the nozzle arm of the processing liquid supply 700. In this state, the chemical liquid whose temperature is adjusted is supplied onto the front surface (top surface) of the wafer W from the chemical liquid nozzle 701 (times t3 to t4). The supply of the chemical liquid is continued until the liquid surface LS of the chemical liquid becomes higher than the top surface of the wafer W. Here, the upper portion 181 of the periphery cover body 180 serves as the bank to suppress the overflow of the chemical liquid to the outside of the rotary table 100.

During or after the supply of the chemical liquid, the rotary table 100 is rotated at a low speed in the forward rotation direction and in the backward rotation direction alternately (for example, by about 180 degrees). Accordingly, the chemical liquid is stirred and the reaction between the front surface of the wafer W and the chemical liquid can be uniform within the surface of the wafer W.

In general, the temperature of the peripheral portion of the wafer W tends to decrease due to the influence of the air flow introduced into the liquid recovery cup. Among the plurality of heater elements 142E of the heater 142, the power to be supplied to the heater elements 142E for heating the peripheral region of the wafer W (the heating zones 143-1 to 143-4 of FIG. 3) may be increased. As a result, the temperature of the wafer W can be uniform within the surface of the wafer W, and, thus, the reaction between the front surface of the wafer W and the chemical liquid can be uniform within the surface of the wafer W.

During this chemical liquid processing, the control over the power to be supplied to the heater 142 may be performed based on the detection values of the temperature sensors 146 provided at the hot plate 140. Instead, the control over the power to be supplied to the heater 142 may be performed based on the detection values of the infrared thermometers 870 configured to detect the surface temperature of the wafer W. When using the detection values of the infrared thermometers 870, it is possible to more accurately control the temperature of the wafer W. The control over the power to be supplied to the heater 142 may be performed based on the detection values of the temperature sensors 146 at an early stage of the chemical liquid processing, and then, performed based on the detection values of the infrared thermometers 870 in a later stage thereof.

[Chemical Liquid Scattering Process (Chemical Liquid Removing Process)]

When the chemical liquid processing is ended, the power feed to the heater 142 from the power feeder 300 is first stopped (time t4), and then, the second electrode unit 161B is moved down to the lowered position (time t5). By stopping the power feed first, it is possible to suppress the generation of the spark between the electrodes when the second electrode unit 161B is lowered.

Then, by rotating the rotary table 100 at a high speed, the chemical liquid on the wafer W is scattered outwards by the centrifugal force (times t5 to t6). Since the inner peripheral surface 185 of the upper portion 181 of the periphery cover body 180 is inclined, all the chemical liquid existing at the inner side in the radial direction than the upper portion 181 (including the chemical liquid on the wafer W) is smoothly removed. The scattered chemical liquid falls down through the passageway 190 between the rotary cup 188 and the periphery cover body 180 so as to be received by the liquid recovery cup 800. Here, the first and second movable cup components 802 and 803 are located at appropriate positions such that the scattered chemical liquid is guided into the discharge passageway (any one of the first discharge passageway 806, the second discharge passageway 807 and the third discharge passageway 808) suitable for the kind of the chemical liquid.

[Rinsing Process]

Thereafter, while the rotary table 100 is rotated at a low speed, the rinse nozzle 702 is located directly above the central portion of the wafer W and the rinse liquid is supplied from the rinse nozzle 702 (times t6 to t7). Accordingly, all the chemical liquid remaining at the inner side in the radial direction than the upper portion 181 (including the chemical liquid remaining on the wafer W) is washed away by the rinse liquid.

The rinse liquid supplied from the rinse nozzle 702 may be a rinse liquid of room temperature or a heated rinse liquid. When supplying the heated rinse liquid, it is possible to suppress the decrease in the temperatures of the attraction plate 120 and the hot plate 140. The heated rinse liquid may be supplied from the factory power supply system. Instead, a heater (not shown) may be provided in the rinse liquid supply line connecting the rinse liquid source 702A and the rinse nozzle 702 in order to heat the rinse liquid of room temperature.

[Scattering Drying Process]

Then, while the rotary table 100 is rotated at a high speed, the discharge of the rinse liquid from the rinse nozzle 702 is stopped and all the rinse liquid remaining at the inner side in the radial direction than the upper portion 181 (including the rinse liquid remaining on the wafer W) is scattered outwards by the centrifugal force (times t7 to t8). Accordingly, the wafer W is dried.

While performing the rinsing processing and the drying processing, the drying accelerator liquid may be supplied onto the wafer W to replace all the rinse liquid remaining at the inner side in the radial direction than the upper portion 181 (including the rinse liquid remaining on the wafer W) with the drying accelerator liquid. Desirably, the drying accelerator liquid may have higher volatility and lower surface tension than the rinse liquid. The drying accelerator liquid may be, for example, IPA (isopropyl alcohol).

After the scattering drying process, a heating and drying process for heating the wafer W may be performed. In this case, the rotation of the rotary table 100 is stopped first. Then, the second electrode unit 161B is moved up to the raised position (time t8). Then, the power is fed from the power feeder 300 to the heater 142 (time t9). Accordingly, the temperature of the wafer W is increased (desirably, at a high speed), and the rinse liquid (or the drying accelerator liquid) remaining at the peripheral portion of the wafer and in the vicinity thereof is removed by evaporation. Since the front surface of the wafer W is dried sufficiently by performing the above-described scattering drying process with IPA, the heating and drying by the heater 142 does not need to be performed. That is, in the time chart of FIG. 8, the operations from the time between the times t7 and t8 and the time between the times t10 to t11 may be omitted.

[Wafer Carry-Out Process]

Thereafter, by switching the switch device (three-way valve) 156, the connection destination of the suction line 155W is changed from the suction device 157W to the purge gas supply device 159. Accordingly, the purge gas is supplied into the plate bottom surface suction path groove 121P and further supplied into the recess regions 125W on the top surface 120A of the attraction plate 120 through the substrate bottom surface suction path groove 122W. As a result, the attraction of the wafer W to the attraction plate 120 is released (time t10).

Along with the above-described operations, the attraction of the attraction plate 120 to the hot plate 140 is also released. Since the attraction of the attraction plate 120 to the hot plate 140 does not need to be released whenever the processings for each wafer W are ended, the pipe system in which this release of the attraction is not performed may be used.

Subsequently, the lift pins 211 are raised to the delivery position (time t11). Since the attraction of the wafer W to the attraction plate 120 is released through the purging, the wafer W can be easily separated from the attraction plate 120. Therefore, it is possible to suppress the damage to the wafer W.

Then, the wafer W placed on the lift pins 211 is lifted by the arm (see FIG. 1) of the substrate transfer device 17 and carried out of the processing unit 16 (time t12). Thereafter, the wafer sensor 860 inspects whether the wafer W does not exist on the attraction plate 120. Through the above-described operations, a series of processings for each wafer W are ended.

The chemical liquid used in the chemical liquid cleaning processing may be, for example, SC1, SPM (sulfuric acid hydrogen peroxide mixture), H₃PO₄ (phosphoric acid aqueous solution), or the like. As an example, the temperature of the SC1 is in the range of from the room temperature to 70° C., the temperature of the SPM is in the range of from 100° C. to 120° C., and the temperature of the H₃PO₄ is in the range of from 100° C. to 165° C. When the chemical liquid is supplied at a temperature higher than room temperature, the above-described exemplary embodiment is advantageous.

According to the above-described exemplary embodiment, since the chemical liquid is heated through thermal conduction within a solid, it is possible to control the temperature of the chemical liquid existing on the wafer W with high accuracy. Further, in the rinsing processing and the scattering drying, the power feed system for the heater 142 is separated, and, thus, the rotary table 100 can be rotated at a high speed. Therefore, the rinsing processing and the scattering drying can be performed efficiently.

Moreover, according to the above-descried exemplary embodiment, since the rotary table 100 can be rotated to some extent without separating the power feed system for the heater 142, the puddle of the processing liquid can be stirred while being heated. Therefore, the uniformity of the processing within the surface of the wafer W can be improved.

As the liquid processing, a plating processing (particularly, an electroless plating processing) may also be performed using the above-described processing unit 16. When the electroless plating processing is performed, a pre-cleaning process (chemical liquid cleaning process), a plating process, a post-cleaning process (chemical liquid cleaning process), an IPA replacement process, a scattering drying process (and a subsequent heating and drying process when necessary) are performed sequentially. In the plating process among these processes, an alkaline chemical liquid (electroless plating liquid) having a temperature ranging from, e.g., 50° C. to 70° C. is used as a processing liquid. Processing liquids (chemical liquids and rinse liquids) used in the pre-cleaning process, the post-cleaning process and the IPA replacement process are all at room temperature. Thus, the plating process may be performed in the same manner as the above-described wafer heating process and chemical liquid processing process. In the pre-cleaning process, the rinsing process, the post-cleaning process and the IPA replacement process, the necessary processing liquids need to be supplied onto the top surface of the wafer W attracted to the attraction plate 120 while the rotary table is rotated in the state where the first electrodes 164A are spaced apart from the second electrodes 164B. Here, the processing liquid supply 700 is equipped with enough nozzles and processing liquid sources to supply the necessary processing liquids.

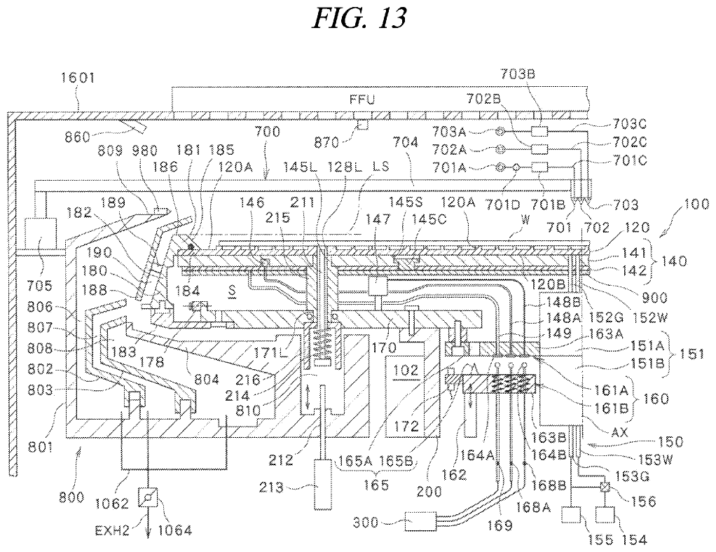

Hereinafter, another configuration example of the processing unit will be described with reference to FIG. 13. In the configuration example shown in FIG. 13, an auxiliary heater 900 having substantially the same planar shape as the heater 142 is provided at the bottom surface of the heater 142. Like the heater 142, the auxiliary heater 900 may be configured as the sheet-type heater, e.g., the polyimide heater. Desirably, an insulating film made of a polyimide film is interposed between the heater 142 and the auxiliary heater 900, each of which may be configured as the polyimide heater.

In the auxiliary heater 900 like the heater 142, a plurality of heating zones may be set and controlled individually. A single heating zone may be set in the heater 142, and the entire region of the heater 142 may be controlled to generate heat uniformly.

Hereinafter, a power feed device for the auxiliary heater 900 will be described. The power feed device has a contact type power transmission mechanism. The power transmission mechanism is configured to feed the power to the auxiliary heater 900 even when the rotary table 100 is continuously rotated in one direction (at this time, the power cannot be fed to the heater 142 via the switch mechanism 160). The power transmission mechanism is configured to be arranged coaxially with the rotary joint 151 and, desirably, mounted on the rotary joint 151 or integrally formed with the rotary joint 151.

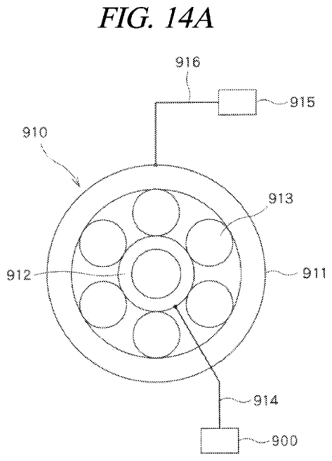

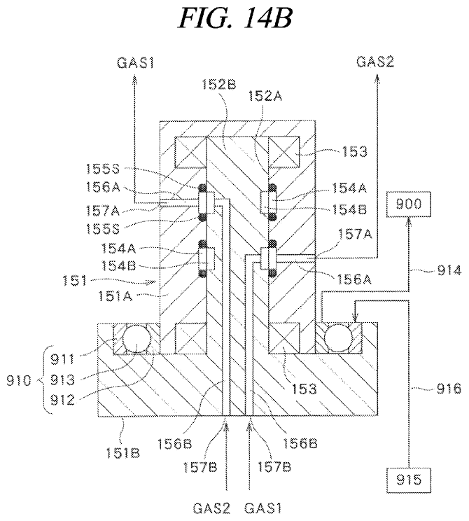

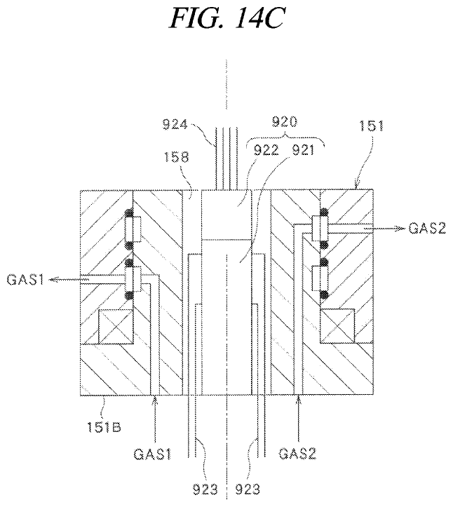

A power transmission mechanism 910 according to the first configuration example will be described with reference to an operational principle diagram of FIG. 14A and an axial cross sectional view of FIG. 14B. As shown in FIG. 14A, the power transmission mechanism 910 has a configuration similar to that of a rolling bearing (a ball or a roller bearing) and is equipped with an outer race 911, an inner race 912 and a plurality of rolling bodies (for example, balls) 913. The outer race 911, the inner race 912 and the rolling bodies 913 are made of a conductive material (conductor). Desirably, an appropriate pre-load is applied between the constituent components 911, 912 and 913 of the power transmission mechanism 910. Accordingly, it is possible to secure more stable conduction between the outer race 911 and the inner race 912 via the rolling bodies 913.

A specific example of the rotary joint 151 equipped with the power transmission mechanism 910 according to the above-described operational principle is shown in FIG. 14B. The rotary joint 151 includes the lower piece 151B fixed to a frame provided within the housing 1601 or fixed to a bracket fixed thereto (both of which are not illustrated), and the upper piece 151A fixed to the rotary table 100 or a member (not shown) configured to be rotated along with the rotary table 100.

Although the configuration of the rotary joint 151 shown in FIG. 14B is well known in the art, it will be briefly explained herein. That is, a columnar central protrusion 152B of the lower piece 151B is inserted in a cylindrical central hole 152A of the upper piece 151A. The central protrusion 152B is supported at the upper piece 151A via a pair of bearings 153. Circumferential grooves 154A are formed in an inner peripheral surface of the central hole 152A, and the number of the circumferential grooves 154A depends on the number of the kinds of gases used (two GAS1 and GAS2 in FIG. 14B, but is not limited thereto). Seal rings 155S configured to suppress a leakage of a gas are provided at both sides of each circumferential groove 154A. Gas passageways 156A respectively communicating with the circumferential grooves 154A are formed within the upper piece 151A. An end portion of each gas passageway 156A is configured as a gas outlet port 157A. A plurality of circumferential grooves 154B is formed in an outer peripheral surface of the central protrusion 152B at axial positions respectively corresponding to the plurality of circumferential grooves 154A. Gas passageways 156B respectively communicating with the plurality of circumferential grooves 154B are formed within the lower piece 151B. An end portion of each gas passageway 156B is configured as a gas inlet port 157B.

According to the configuration shown in FIG. 14B, even when the upper piece 151A and the lower piece 151B are rotated, a gas can be flowed between the gas inlet port 157B and the gas outlet port 157A without a substantial leakage of a gas. A suction force can also be transferred between the gas inlet port 157B and the gas outlet port 157A.

The power transmission mechanism 910 is provided between the upper piece 151A and the lower piece 151B of the rotary joint 151. In the example shown in FIG. 14B, the outer race 911 is inserted and fitted (for example, press-fitted) into a cylindrical recess portion of the lower piece 151B, and a columnar outer peripheral surface of the upper piece 151A is inserted and fitted (for example, press-fitted) into the inner race 912. Electrical insulation has been performed appropriately between the outer race 911 and the lower piece 151B and between the upper piece 151A and the inner race 912. The outer race 911 is electrically connected to a power supply (or a power feed controller) 915 via a wire 916 and the inner race 912 is electrically connected to the auxiliary heater 900 via a wire 914. Further, in the example shown in FIG. 14B, the inner race 912 is a rotary member configured to be rotated as one body with the rotary table 100 and the outer race 911 is a non-rotary member. The power supply 915 may be a part of the power feeder 300 shown in FIG. 13.

Further, in the configuration shown in FIG. 14B, the power transmission mechanism 910 is equipped with rolling bearings at multiple levels in the axial direction, and, thus, it is possible to feed the power through multiple channels. In this case, a plurality of heating zones may be provided in the auxiliary heater 900, and, thus, it is possible to feed the power to each heating zone independently.

Hereinafter, a power transmission mechanism 920 according to a second configuration example will be described with reference to FIG. 14C. The power transmission mechanism 920 shown FIG. 14C is configured as a well-known slip ring and configured to feed a power through multiple channels. The slip ring is composed of a rotary ring as a conductor and a brush. The slip ring is composed of a fixed part 921 and a rotary part 922. The fixed part 921 is fixed to the frame provided within the housing 1601 or fixed to the bracket fixed thereto (both of which are not illustrated). The rotary part 922 is fixed to the rotary table 100 or the member (not shown) configured to be rotated along with the rotary table 100. On a side peripheral surface of the fixed part 921, a plurality of ports connected to a plurality of wires 923, which are electrically connected to a power supply or a power feed controller (not shown), is provided. A plurality of wires 924 respectively communicating with the plurality of ports extends from an end surface of the rotary part 922 in the axial direction so as to be electrically connected to the auxiliary heater 900.

In the configuration example of FIG. 14C, the lower piece 151B of the rotary joint 151 is configured as a hollow member having a through hole 158 at a center thereof. The power transmission mechanism 920 configured as the slip ring is provided within the through hole 158. As in the configuration example of FIG. 14B, the lower piece 151B of the rotary joint 151 is fixed to the frame provided within the housing 1601 or fixed to the bracket fixed thereto (both of which are not illustrated). Further, the upper piece 151A of the rotary joint 151 is fixed to the rotary table 100 or the member (not shown) configured to be rotated along with the rotary table 100.

Further, a distributor (not shown) configured to distribute the power transmitted through the power transmission mechanism into multiple channels and a control module (not shown) configured to control the power feed to each heating zone may be provided at an appropriate portion within the space S between the hot plate 140 and the support plate 170. Accordingly, even if the power transmission mechanism is designed to correspond to a single channel, a plurality of heating zones is provided in the auxiliary heater 900, and, thus, it is possible to feed the power to each heating zone independently.

A power feed device configured to feed the power to the auxiliary heater 900 is not limited to the above-described examples. The power feed device may include a power supply device using any one well-known power transmission mechanism having the power transmitting part and the power receiving part configured to be rotated relative to each other while transmitting the power at a desired level.

If the power transmission mechanism is configured to transmit the power through multiple channels, one or more transmission channels may be used to transmit the control signal or the detection signal.

Moreover, the power transmission mechanism shown in FIG. 13 and FIG. 14A to FIG. 14C may perform all or a part of a function of feeding the power to the main heater 142 via the switch mechanism 160 as described above with reference to FIG. 2 and FIG. 11 and a function of transmitting the control/detection signals. In this case, the switch mechanism 160 may be completely omitted, or a part of the components of the switch mechanism 160 may be omitted.

An operation of the processing unit 16 shown in FIG. 13 is performed in the same manner as the above-described operation of the processing unit 16 of FIG. 2 except the power feed to the auxiliary heater 900.

In an exemplary embodiment, the auxiliary heater 900 is continuously fed with the power. In the exemplary embodiment, the power supplied to the heater (main heater) 142 via the switch mechanism 160 is greater than power supplied to the auxiliary heater 900 via the power transmission mechanisms 910 and 920 shown in FIG. 14A to FIG. 14C and the power transmission mechanisms 902 and 903 shown in FIG. 13. That is, a main function of the auxiliary heater 900 is to suppress the decrease in the temperature of the hot plate 140 when the heating by the heater 142 cannot be performed. A caloric power of the auxiliary heater 900 may be substantially equal to a caloric power of the heater 142.

Further, in the exemplary embodiment, while the processing unit 16 (substrate processing system 1) is being operated, the power is constantly supplied to the auxiliary heater 900, and the control over the temperature of the wafer W is performed by adjusting the power to be supplied to the heater 142. By adjusting the power to be supplied to the auxiliary heater 900, the auxiliary heater 900 may also be involved in the temperature control of the wafer W.

Furthermore, in the above-described exemplary embodiment, the heater (main heater) 142, i.e., a first heater element and the auxiliary heater 900, i.e., a second heater element supplied with the power by the independent power feed systems, respectively, are provided. However, the present disclosure is not limited thereto. For example, the auxiliary heater 900 may not be provided and the main heater 142 may be supplied with the power by a first power feed system including the above-described switch mechanism 160 and a second power feed system including the above-described power transmission mechanisms 910 and 920 and the power transmission mechanisms 902 and 903.

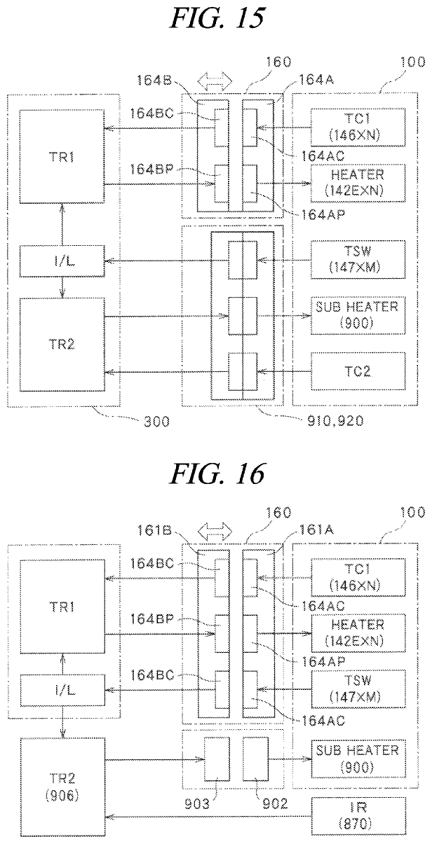

Hereinafter, examples of a relationship between elements involved in the temperature control by the heater will be described with reference to FIG. 15 and FIG. 16.

First, an example shown in FIG. 15 will be described. In the example of FIG. 15, a power is supplied and a control signal (or detection signal) is transmitted by using the switch mechanism 160 configured to perform the above-described contact and separation operation and the power transmission mechanism 910 (or 920) configured to continuously feed the power.

Detection signals of N number (for example, ten equal to the number of the heating zones) of the temperature sensors 146 (for example, thermocouples TC1) are sent to a temperature controller TR1 embedded in the power feeder 300 (see FIG. 13) via a first electrode 164AC and a second electrode 164BC for control signal communication of the switch mechanism 160. Further, in this case, the power feeder 300 includes the above-described power supply 915.

The temperature controller (regulator) TR1 is configured to calculate the powers to be supplied to the respective heater elements 142E of the heater 142 based on the received detection signals of the temperature sensors TC1. Further, the temperature controller TR1 is configured to supply powers corresponding to the calculated powers to the heater elements 142E via a first electrode 164AP and a second electrode 164BC for heater power feed of the switch mechanism 160.

If an abnormal increase in the temperature of the hot plate 140 is detected by any one of M number of (for example, three) thermo switches 147, this detection result is sent to an interlock controller I/L via one or more transmission channels of the power transmission mechanism 910. The interlock controller I/L is configured to control the temperature controller TR1 to stop the power feed to the heater 142.

A detection signal of a temperature sensor TC2 (not shown except in FIG. 15) such as a thermocouple provided in the hot plate 140 is sent to a temperature controller (regulator) TR2 embedded in the power feeder 300 by using one or more transmission channels of the power transmission mechanism 910. The temperature controller TR2 is configured to calculate the power to be supplied to the auxiliary heater 900 based on the received detection signal of the temperature sensor TC2. The temperature controller TR2 is configured to supply the power corresponding to the calculated power to the auxiliary heater 900 via the power transmission mechanism 910. Alternatively, as described above, the power may be constantly supplied to the auxiliary heater 900.

Hereinafter, an example shown in FIG. 16 will be described. In the example of FIG. 16, a power is supplied and a control signal (or detection signal) is transmitted by the switch mechanism 160 configured to perform the above-described contact and separation operation and by the non-contact type power transmission mechanisms 902 and 903. In the following, only distinctive features from the example of FIG. 15 will be described.

In the example of FIG. 16, the detection signal of the abnormal temperature increase from the thermo switch 147 is sent to the temperature controller TR1 embedded in the power feeder 300 via the first electrode 164AC and the second electrode 164BC for control signal communication of the switch mechanism 160. Further, in the example of FIG. 16, the surface temperature of the wafer W or the attraction plate 120 (if there is no wafer W) is detected by an infrared thermometer 870 instead of the temperature sensor TC2 such as the thermocouple provided in the hot plate 140. Based on this detection result, the temperature controller TR2 supplies the power to the auxiliary heater 900 via the power transmission mechanism 910.

Although not shown in FIG. 15 and FIG. 16, when it is required to take earth, one transmission channel of the switch mechanism 160 or the power transmission mechanism 910 (920) may be used.

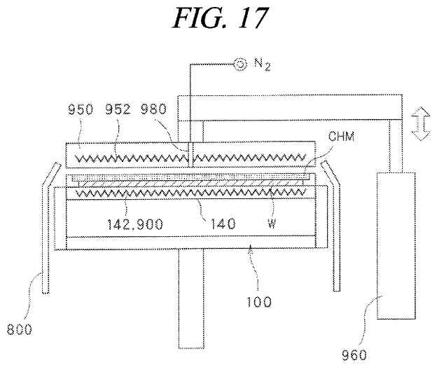

As schematically shown in FIG. 17, a circular plate-shaped top plate 950 having substantially the same diameter as that of the wafer W may be provided within the processing unit 16. The top plate 950 may have a heater 952 embedded therein. The top plate 950 can be moved by a plate moving mechanism 960 between a cover position (a position shown in FIG. 17) close to the wafer W held on the rotary table 100 and a standby position sufficiently apart from the wafer W (for example, a position where the nozzle arm 704 can be located above the wafer W). The standby position may be a position directly above the rotary table 100 or a position at an outer side than the liquid recovery cup 800 when viewed from the top.

If the top plate 950 is provided, the top plate 950 is located at the cover position while the above-described chemical liquid processing is performed. That is, the top plate 950 is placed near the liquid surface of the puddle of the chemical liquid CHM covering the wafer W. In this case, contamination within the processing unit 16 caused by the scattering of the chemical liquid components can be suppressed by the top plate 950.

If the top plate 950 has the heater 952, the top plate 950 has a function to maintain the temperatures of the wafer W and the chemical liquid on the wafer W. Further, since a bottom surface of the top plate 950 is heated by the heater 952, vapor (water vapor) generated from the chemical liquid heated on the wafer W does not condense on the bottom surface of the top plate 950. For this reason, since a vapor pressure of a space (gap) between the surface of the liquid film of the chemical liquid and the bottom surface of the top plate 950 is maintained, the evaporation of the chemical liquid is suppressed. Thus, it is possible to maintain a concentration of the chemical liquid within a desired range. Also, it is possible to suppress an increase in the consumption amount of the chemical liquid. Further, it is possible to suppress the contamination of the bottom surface of the top plate 950. A set temperature of the heater 952 of the top plate 950 does not need to be as high as a set temperature of the spin chuck and just needs not to cause the condensation on the bottom surface of the top plate 950. This effect can be obtained even when the chemical liquid is a chemical liquid for wet etching, a chemical liquid for cleaning or a chemical liquid (plating liquid) for plating (electroless plating).

The top plate 950 may be equipped with a gas nozzle 980 configured to supply an inert gas, for example, a nitrogen gas (N₂ gas) into a space under the top plate 950. Since an oxygen concentration in the space between the top surface of the wafer W and the bottom surface of the top plate 950 can be reduced by the inert gas supplied from the gas nozzle 980, this configuration may be advantageous in various processings in which an oxidizing atmosphere is not desired. For example, in the electroless plating processing, suppressing the oxidation of the plating liquid is advantageous to improve the quality of the plating film.

A circumferential wall protruding downwards from an outer periphery of the bottom surface of the top plate 950 may be provided. Since the space between the top surface of the wafer W and the bottom surface of the top plate 950 is surrounded by the circumferential wall, an atmosphere of the inert gas supplied from the nozzle 980 can be efficiently controlled.

As described briefly above, the plating processing (particularly, electroless plating processing) can be performed as the liquid processing using the processing unit 16 (shown in FIG. 2 or FIG. 13). This will be described in detail below.

First, when the plating processing is performed in the processing unit 16, the top plate 950 described above with reference to FIG. 17 is provided in the processing unit 16. Further, the nozzle arm 704 is equipped with four nozzles having the same configuration as the nozzles 701 to 703 described above. The four nozzles are respectively supplied with four kinds of processing liquids from liquid sources which are the same as the above-described sources 701A to 703A through pipes equipped with liquid supply mechanisms having the same configuration as the above-described liquid supply mechanisms 701B to 703B including the flow control devices. In the exemplary embodiment, the four kinds of processing liquids include a pre-cleaning liquid, a plating liquid (plating liquid for electroless plating), a post-cleaning liquid, and a rinse liquid.

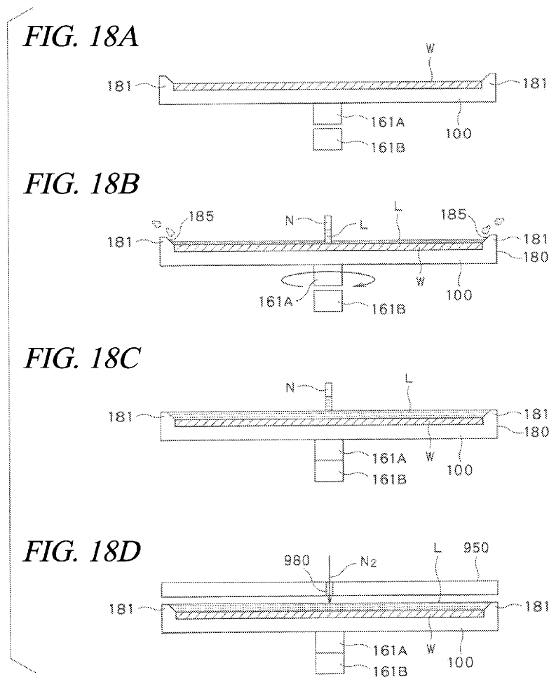

Hereinafter, each process of the plating processing will be described. In the following description, schematic diagrams of FIGS. 18A to 18D are also referred to. In the schematic diagrams of FIGS. 18A to 18D, L is a processing liquid (any one of the above-described four kinds of processing liquids) and N is any one of the above-described four nozzles.

[Wafer W Carry-in Process (Holding Process)]

First, a wafer W carry-in process (holding process) is performed. This process is the same as the wafer W carry-in process (holding process) in the chemical liquid cleaning processing, and a repeated description thereof will be omitted. Here, as shown in the schematic diagram of FIG. 18A, the first electrode unit 161B and the second electrode unit 161B are separated from each other and the power feed from the power feeder 300 to the heater 142 is stopped.

[Pre-Cleaning Process]

Then, the pre-cleaning liquid is supplied from the nozzle for supplying the pre-cleaning liquid onto the central portion of the surface of the wafer W while the rotary table 100 holding the wafer W is rotated. The pre-cleaning liquid supplied onto the wafer W flows while spreading toward a periphery of the wafer W due to the centrifugal force, and flows out from the periphery of the wafer W. Here, the surface of the wafer W is covered with a thin liquid film of the pre-cleaning liquid. Through the pre-cleaning process, the surface of the wafer W comes into a state suitable for the plating processing. At this time, the first electrode unit 161B and the second electrode unit 161B are separated from each other and the power feed from the power feeder 300 to the heater 142 is stopped. The state at this time is shown in the schematic diagram of FIG. 18B. The processing liquid L (pre-cleaning liquid) flowing out from the periphery of the wafer W is scattered to the outside of the rotary table 100 along the inclined inner peripheral surface 185 of the upper portion 181 of the periphery cover body 180.

[First Rinsing Process]

Thereafter, while the rotary table 100 is kept rotating, the supply of the pre-cleaning liquid is stopped and the rinse liquid (for example, DIW) is supplied from the nozzle for supplying the rinse liquid onto the central portion of the surface of the wafer W held on the rotary table. The rinse liquid supplied onto the wafer W washes away the pre-cleaning liquid and reaction by-products remaining on the wafer W. At this time, the first electrode unit 161B and the second electrode unit 161B are separated from each other and the power feed from the power feeder 300 to the heater 142 is stopped. The state at this time is the same as shown in FIG. 18B (however, the processing liquid L is the rinse liquid).

[Plating Liquid Replacement Process]

Subsequently, while the rotary table 100 is kept rotating, the supply of the rinse liquid is stopped and the plating liquid is supplied from the nozzle for supplying the plating liquid onto the central portion of the surface of the wafer W held on the rotary table. Thus, the rinse liquid remaining on the wafer W is replaced by the plating liquid. The state at this time is the same as shown in FIG. 18B (however, the processing liquid L is the plating liquid).

Desirably, an inert gas (for example, nitrogen gas) is supplied into the housing 1601 to reduce an oxygen concentration in the housing 1601 before the supply of the plating liquid to the surface of the wafer W is started. An FFU (fan filter unit) provided at the ceiling of the housing 1601 can serve as an inert gas supply configured to supply the inert gas into the housing 1601. In this case, the FFU has a function to supply clean air and a function to supply an inert gas. Instead, an inert gas supply including a nozzle for supplying an inert gas into the housing 1601 may be provided separately from the FFU. By suppressing the oxidation of the plating liquid, the quality of the plating film can be improved.

[Wafer Heating Process]

When the rinse liquid is replaced with the plating liquid, the rotation of the wafer W is stopped while the supply of the plating liquid is continued. Then, the second electrode unit 161B is moved to the raised position so that the plurality of first electrodes 164A of the first electrode unit 161A and the plurality of second electrodes 164B of the second electrode unit 161B are brought into contact with each other. Subsequently, the power supply to the heater 142 of the plate 140 is started. Here, the power to be supplied to the heater 142 of the hot plate 140 is adjusted to allow the temperature of the hot plate 140 to reach a predetermined temperature (a temperature at which the wafer W on the attraction plate 120 can be heated to a temperature suitable for a subsequent plating processing).

[Plating Process (Including Puddle Forming Process and Stirring Process)]

After or concurrently with the wafer heating process, a puddle (liquid accumulation) of the plating liquid is formed on the surface of the wafer W. When the rotation of the wafer W is stopped while the supply of the plating liquid is continued after the rinse liquid is replaced with the plating liquid, the thickness of the liquid film of the plating liquid formed on the surface of the wafer W increases. The state at this time is shown in FIG. 18C (however, the processing liquid L is the plating liquid). The supply of the plating liquid is continued until, for example, the height of the surface of the liquid film of the plating liquid is slightly lower than the height of the upper portion 181 of the periphery cover body 180 and then, the supply of the plating liquid is stopped. The upper portion 181 of the periphery cover body 180 serves as the bank to suppress the overflow of the plating liquid to the outside of the rotary table 100.

When the puddle of the plating liquid having a desired thickness is formed, the nozzle for supplying the plating liquid and the nozzle arm holding the nozzle (for example, the nozzle arm 704 shown in FIG. 2 and FIG. 13) are retreated from above the wafer W. Then, as shown in FIG. 17 and FIG. 18D, the top plate 950 is located at the cover position. That is, the top plate 950 is brought close to the surface of the liquid film of the plating liquid formed on the surface of the wafer W. Further, the heater 952 embedded in the top plate 950 is fed with the power to heat at least the bottom surface of the top plate 950.

Here, as described above, the top plate 950 serves to maintain the temperatures of the wafer W and the plating liquid on the wafer W, control the atmosphere around the plating liquid on the wafer W and maintain the concentration of the plating liquid on the wafer W.

Desirably, while the top plate 950 is located at the cover position, the inert gas, such as nitrogen gas, is supplied from the gas nozzle 980 provided in the top plate 950 to a space between the surface of the liquid film of the plating liquid on the wafer W and the bottom surface of the top plate 950, and, thus, the space has the low oxygen concentration atmosphere. Accordingly, it is possible to suppress the deterioration of the plating liquid caused by the oxidation and improve the quality of the plating film.

Desirably, during or after the supply of the plating liquid, the rotary table 100 is rotated at a low speed in the forward rotation direction and in the backward rotation direction alternately (for example, by about 180 degrees). Accordingly, the plating liquid is stirred and the reaction between the front surface of the wafer W and the plating liquid can be uniform within the surface of the wafer W. As described above, the rotary table 100 can be rotated by about ±180 degrees while the first electrode unit 161B and the second electrode unit 161B are kept in contact with each other.

During the plating process, the first electrode unit 161A and the second electrode unit 161B are kept in contact with each other. In the plating process similar to the above-described chemical liquid processing process, the control over the power to be supplied to the heater 142 can be performed based on the detection values of the temperature sensors 146 provided at the hot plate 140. Instead, the control over the power to be supplied to the heater 142 may be performed based on the detection values of the infrared thermometers 870 configured to detect the surface temperature of the wafer W. When using the detection values of the infrared thermometers 870, it is possible to more accurately control the temperature of the wafer W. The control over the power to be supplied to the heater 142 may be performed based on the detection values of the temperature sensors 146 at an early stage of the plating process and then performed based on the detection values of the infrared thermometers 870 in a later stage thereof.

In the plating process similar to the above-described chemical liquid processing process, the power to be supplied to the heater elements 142E for heating the peripheral region of the wafer W (the heating zones 143-1 to 143-4 of FIG. 3) may be increased. As a result, the temperature of the wafer W can be uniform within the surface of the wafer W, and, thus, the reaction between the front surface of the wafer W and the plating liquid can be uniform within the surface of the wafer W.

When the desired plating film is formed, the top plate 950 is moved to the retreat position and the power supply from the power feeder 300 to the heater 142 is stopped. Then, the second electrode unit 161B is moved to the lowered position so that the first electrodes 164A are separated from the second electrodes 164B.

[Second Rinsing Process]

Thereafter, the rotary table 100 holding the wafer W is rotated and the rinse liquid (for example, DIW) is supplied from the nozzle for supplying the rinse liquid onto the central portion of the surface of the wafer W held on the rotary table. The rinse liquid supplied onto the wafer W washes away the plating liquid and the reaction by-products remaining on the wafer W. At this time, the first electrode unit 161B and the second electrode unit 161B are separated from each other and the power feed from the power feeder 300 to the heater 142 is continuously stopped. The state at this time is the same as shown in FIG. 18B (however, the processing liquid L is the rinse liquid).

[Post-Cleaning Process]

Subsequently, while the rotating table 100 is kept rotating, the post-cleaning liquid is supplied from the nozzle for supplying the post-cleaning liquid onto the central portion of the surface of the wafer W. The post-cleaning liquid supplied onto the wafer W further washes away the reaction by-products remaining on the wafer W. At this time, the power feed from the power feeder 300 to the heater 142 is continuously stopped. By stopping the power feed to the heater 142, it is possible to suppress the etching of the plating film which may occur when the temperature of the post-cleaning liquid, which is a low concentration alkaline solution, increases. The state at this time is the same as shown in FIG. 18B (however, the processing liquid L is the post-cleaning liquid).

[Third Rinsing Process]

Then, while the rotary table 100 is kept rotating, the rinse liquid (for example, DIW) is supplied from the nozzle for supplying the rinse liquid onto the central portion of the surface of the wafer W held on the rotary table. The rinse liquid supplied onto the wafer W washes away the post-cleaning liquid and the reaction by-products remaining on the wafer W. At this time, the power feed from the power feeder 300 to the heater 142 is continuously stopped. The state at this time is the same as shown in FIG. 18B (however, the processing liquid L is the rinse liquid).

[Scattering Drying Process]

Then, while the rotary table 100 is rotated at a high speed, the discharge of the rinse liquid from the nozzle for supplying the rinse liquid is stopped and all the rinse liquid remaining at the inner side in the radial direction than the upper portion 181 (including the rinse liquid remaining on the wafer W) is scattered outwards by the centrifugal force. Accordingly, the wafer W is dried. At this time, the power feed from the power feeder 300 to the heater 142 is continuously stopped.

As in the chemical liquid cleaning processing, the heating and drying process for heating the wafer W may be performed after the scattering drying process.

[Wafer Carry-Out Process]

Thereafter, a wafer carry-out process is performed in the same sequence as that of the wafer carry-out process in the chemical liquid cleaning processing. At this time, the power feed from the power feeder 300 to the heater 142 is continuously stopped.

A series of processes of the plating processing for a single wafer W are thus completed.

Even in the case of performing the above-described plating processing, the advantages obtained by performing the chemical liquid processing described above can also be obtained.

After the first rinsing process and before the plating liquid replacement process, a palladium applying process for applying palladium, which serves as a catalyst for precipitation of a plating film, to the wafer W may be performed. In order to perform this palladium applying process, a liquid supply mechanism including a nozzle for supplying a palladium catalyst solution to the wafer W and a flow control device for supplying the palladium catalyst solution to the nozzle from a palladium catalyst solution source is provided (all of which are not illustrate). After the palladium applying process and before the plating liquid replacement process, another rinsing process may be performed.

Before the post-cleaning process is started, a cooling process for cooling the rotary table 100 may be performed. The cooling of the rotary table 100 may be performed, for example, in the following sequence. First, the attraction of the wafer W to the attraction plate 120 of the rotary table 100 is released. Then, the wafer W is lifted by the lift pins 211 and separated from the attraction plate 120. Thereafter, the suction force is applied to the substrate suction hole 144W to suction the atmosphere around the top surface of the attraction plate 120. Here, desirably, the suction is performed using an ejector without using a suction line (factory exhaust system) as the factory power supply and the exhaust is performed through an organic exhaust line.

When the gas (clean air or nitrogen gas) at substantially room temperature is introduced into the substrate suction hole 144W, the gas removes heat, and, thus, the attraction plate 120 and the plate (for example, the hot plate 140) in contact with the attraction plate 120 are cooled. When the attraction plate 120 is cooled to a desired temperature, the lift pins 211 lifting the wafer W are lowered and the wafer W is placed on the attraction plate 120. Then, the suction force is applied to the substrate suction hole 144W to attract the wafer W to the attraction plate 120.

Through the above-described cooling process, the attraction plate 120 is cooled. The temperature of the wafer W separated from the attraction plate 120 during the cooling process also decreases. When the post-cleaning liquid comes into contact with the high temperature wafer W (i.e., the plating film), the plating film may be etched to a problematic degree. However, by performing the cooling process, it is possible to suppress the problem of etching the plating film.

When the processing unit shown in FIG. 13 is used, the power may be continuously supplied to the auxiliary heater 900 while all the above-described processes, i.e., the wafer W carry-in process (holding process), the wafer heating process, the chemical liquid processing process (including the puddle forming process and the stirring process), the chemical liquid scattering process (chemical liquid removing process), the rinsing process, the scattering drying process and the wafer carry-out process, are performed. In this case, different controls may be performed within a period (contact period) during which the first electrodes 164A of the first electrode unit 161A and the second electrodes 164B of the second electrode unit 161B of the switch mechanism 160 are in contact with each other to allow the power to be fed to the heater (main heater) 142 and within a period (separation period) during which the first electrodes 164A are separated from the second electrodes 164B.

Specifically, for example, within the contact period, the temperature of the hot plate 140 of the rotary table 100 is controlled by controlling the power to be supplied to the heater 142, and the auxiliary heater 900 may be supplied with the constant power. Also, within the separation period, the temperature of the hot plate 140 is controlled by controlling the power to be supplied to the auxiliary heater 900.

Within the contact period, the temperature of the hot plate 140 of the rotary table 100 may be controlled by controlling both the power to be supplied to the heater 142 and the power to be supplied to the auxiliary heater 900.

In another exemplary embodiment, within the contact period, the temperature of the hot plate 140 may be controlled only by controlling the power to be supplied to the heater 142 without supplying the power to the auxiliary heater 900.

The temperature of the hot plate 140 within the separation period may be different from, for example, lower than the temperature of the hot plate 140 in the chemical liquid processing process (which is a part of the contact period).

Within the separation period, the temperature of the hot plate 140 (and the attraction plate 120 thereon) decreases due to natural heat radiation or cooling with the processing liquid at room temperature. When the plating process is performed, it takes a relatively long time to increase the decreased temperatures of the hot plate 140 and the attraction plate 120 to the desired temperatures again. This causes the reduction in processing throughput. By supplying the power to the auxiliary heater 900 to maintain the temperature of the hot plate 140 within the separation period, it is possible to reduce the time required to increase the temperatures of the hot plate 140 and the attraction plate 120 to the desired temperatures again.

As described above, it is not desirable that the temperatures of the hot plate 140 and the attraction plate 120 are high when the post-cleaning process is performed. Therefore, it is desirable to start the power supply to the auxiliary heater 900 after the end of the post-cleaning process.

The exemplary embodiments disclosed herein are illustrative in all aspects and do not limit the present disclosure. The above-described exemplary embodiments may be omitted, substituted, or changed in various forms without departing from the scope and spirit of the appended claims.

The substrate to be processed is not limited to the semiconductor wafer and may be another substrate, such as a glass substrate or a ceramic substrate, used in the manufacture of the semiconductor device.

### EXPLANATION OF REFERENCE NUMERALS

W: Substrate
100: Rotary table
102: Rotation driving mechanism
142: Electric heater
164AP(164A): Power receiving electrode
164BP(164B): Power feeding electrode
162: Electrode moving mechanism
300: Power feeder
800: Processing cup
701, 702, 703: Processing liquid nozzle
701B, 702B, 703B: Processing liquid supply mechanism
4, 18: Controller

1. A substrate processing apparatus, comprising:
a rotary table configured to horizontally hold a substrate;
a rotation driving mechanism configured to rotate the rotary table around a vertical axis;
an electric heater provided in the rotary table to be rotated along with the rotary table and configured to heat the substrate placed on the rotary table;
a power receiving electrode provided in the rotary table to be rotated along with the rotary table and electrically connected to the electric heater;
a power feeding electrode configured to be contacted with the power receiving electrode and configured to supply a power to the electric heater via the power receiving electrode;
an electrode moving mechanism configured to allow the power feeding electrode and the power receiving electrode to be relatively contacted with and separated from each other;
a power feeder configured to supply the power to the power feeding electrode;
a processing cup provided to surround the rotary table and connected to an exhaust line and a drain line;
at least one processing liquid nozzle configured to supply a processing liquid onto the substrate;
a processing liquid supply mechanism configured to supply at least an electroless plating liquid as the processing liquid into the at least one processing liquid nozzle; and
a controller configured to control the electrode moving mechanism, the power feeder, the rotation driving mechanism and the processing liquid supply mechanism.

2. The substrate processing apparatus of claim 1,
wherein the rotary table has an attraction plate,
the substrate is attracted to a top surface of the attraction plate to be held on the rotary table, and
the electric heater heats the substrate attracted to the top surface of the attraction plate via the attraction plate from a bottom surface side of the attraction plate.

3. The substrate processing apparatus of claim 2,
wherein an area of the rotary table when viewed from a direction of the vertical axis is equal to or larger than an area of the substrate.

4. The substrate processing apparatus of claim 2, further comprising:
a suction line extending through an inside of a rotation shaft of the rotary table,
wherein the rotary table further includes a base plate,
a suction hole communicating with the suction line is formed at a top surface of the base plate,
the attraction plate is attracted to the base plate by applying a suction force via the suction hole in a state where the attraction plate is placed on the top surface of the base plate, and
the suction force acts on the substrate via a through hole, which is formed through the attraction plate, to attract the substrate to the attraction plate.

5. The substrate processing apparatus of claim 1,
wherein the rotary table has a bank surrounding a peripheral portion of the substrate,
the electroless plating liquid supplied onto the substrate when the substrate is held on the rotary table is blocked by the bank, so that a puddle of the electroless plating liquid in a sufficient amount to immerse an entire top surface of the substrate is formed on the rotary table, and
the bank is inclined to be lowered as the bank approaches an inner side in a radial direction of the rotary table.

6. The substrate processing apparatus of claim 1,
wherein the rotary table is configured to be rotated within a predetermined angular range in a state where the power receiving electrode and the power feeding electrode are in contact with each other.

7. The substrate processing apparatus of claim 1, further comprising:
a processing liquid temperature adjustment mechanism configured to adjust a temperature of the electroless plating liquid before the electroless plating liquid is supplied onto the substrate from the at least one processing liquid nozzle.

8. The substrate processing apparatus of claim 1,
wherein the electric heater includes multiple heating elements configured to heat different regions, respectively, of the substrate, and
the controller is configured to control calorific powers of the multiple heating elements individually via the power feeder.

9. The substrate processing apparatus of claim 1,
wherein the processing liquid supply mechanism is configured to supply a pre-cleaning liquid, a post-cleaning liquid and a rinse liquid to the at least one processing liquid nozzle.

10. The substrate processing apparatus of claim 1, further comprising:
a housing that accommodates the rotary table and the processing cup; and
an inert gas supply configured to supply an inert gas into the housing.

11. The substrate processing apparatus of claim 1, further comprising:
a top plate configured to cover the substrate held on the rotary table.

12. The substrate processing apparatus of claim 11,
wherein the top plate has a heater, and
at least a bottom surface of the top plate is heated by the heater.

13. The substrate processing apparatus of claim 11, further comprising:
an inert gas supply configured to supply an inert gas to a space between the substrate held on the rotary table and the top plate.

14. The substrate processing apparatus of claim 1, further comprising:
a first power transmission mechanism and a second power transmission mechanism configured to supply the power to the electric heater,
wherein the first power transmission mechanism includes the power receiving electrode and the power feeding electrode configured to be contacted with and separated from each other by the electrode moving mechanism,
the second power transmission mechanism includes a fixed part and a rotary part configured to be rotated relative to each other,
the second power transmission mechanism is configured to supply the power from the fixed part to the rotary part even when the rotary part is being continuously rotated with respect to the fixed part,
the rotary part is electrically connected to the electric heater, and fixed to the rotary table or a member configured to be rotated along with the rotary table,
the power feeder is configured to supply the power to the fixed part of the second power transmission mechanism, and
the controller is configured to supply the power to the electric heater from the power feeder via the second power transmission mechanism for at least a part of a separation period during which at least the power receiving electrode is separated from the power feeding electrode.

15. A substrate processing method of processing a substrate by using a substrate processing apparatus including: a rotary table configured to horizontally hold the substrate; a rotation driving mechanism configured to rotate the rotary table around a vertical axis; an electric heater provided in the rotary table to be rotated along with the rotary table and configured to heat the substrate placed on the rotary table; a power receiving electrode provided in the rotary table to be rotated along with the rotary table and electrically connected to the electric heater; a power feeding electrode configured to be contacted with the power receiving electrode and configured to supply a power to the electric heater via the power receiving electrode; an electrode moving mechanism configured to allow the power feeding electrode and the power receiving electrode to be relatively contacted with and separated from each other; a power feeder configured to supply the power to the power feeding electrode; a processing cup provided to surround the rotary table and connected to an exhaust line and a drain line; a processing liquid nozzle configured to supply a processing liquid onto the substrate; and a processing liquid supply mechanism configured to supply at least an electroless plating liquid as the processing liquid into the processing liquid nozzle, the substrate processing method comprising:
horizontally holding the substrate on the rotary table;
forming a puddle of the electroless plating liquid configured to immerse an entire top surface of the substrate by supplying the electroless plating liquid onto the top surface of the substrate; and
processing the substrate with the electroless plating liquid by heating the substrate and the electroless plating liquid on the substrate while feeding the power to the electric heater from the power feeder in a state where the power receiving electrode is in contact with the power feeding electrode.

16. The substrate processing method of claim 15,
wherein the processing of the substrate with the electroless plating liquid includes stirring the electroless plating liquid on the substrate by rotating the rotary table in a forward rotation direction and in a backward rotation direction within a predetermined angular range in a state where the power receiving electrode is in contact with the power feeding electrode to feed the power to the electric heater.

17. The substrate processing method of claim 15, further comprising:
cleaning, after the processing of the substrate with the electroless plating liquid, a front surface of the substrate with a post-cleaning liquid by supplying the post-cleaning liquid onto the top surface of the substrate while rotating the rotary table in a state where the power receiving electrode is separated from the power feeding electrode;
removing the post-cleaning liquid on the substrate with a rinse liquid by supplying the rinse liquid onto the top surface of the substrate while rotating the rotary table in a state where the power receiving electrode is separated from the power feeding electrode; and
scattering, after the removing of the post-cleaning liquid, the rinse liquid on the substrate by stopping the supplying of the rinse liquid and rotating the rotary table.

18. The substrate processing method of claim 17, further comprising:
removing, after the scattering of the rinse liquid, the rinse liquid remaining on the substrate by heating the substrate while stopping the rotary table and feeding the power to the electric heater from the power feeder in a state where the power receiving electrode is in contact with the power feeding electrode.

19. The substrate processing method of claim 15,
wherein the rotary table has an attraction plate,
the holding of the substrate is performed by attracting the substrate to the attraction plate, and
the heating of the substrate in the processing of the substrate with the electroless plating liquid is performed by heating the substrate, which is attracted to a top surface of the attraction plate, with the electric heater via the attraction plate from a bottom surface side of the attraction plate.

20. The substrate processing method of claim 18, further comprising:
separating, after the scattering of the rinse liquid or the removing of the rinse liquid, the substrate from the rotary table by releasing the attracting,
wherein, in the separating of the substrate, a purge gas is flowed into a suction line provided in an attraction plate of the rotary table to accelerate the separating of the substrate.

21. The substrate processing method of claim 15,
wherein the substrate processing apparatus further includes a housing that accommodates the rotary table and the processing cup, and
wherein the substrate processing method further includes supplying an inert gas into the housing before the forming of the puddle of the electroless plating liquid.

22. The substrate processing method of claim 15,
wherein the processing of the substrate with the electroless plating liquid is performed while covering the substrate held on the rotary table with a top plate of which at least a bottom surface is heated.

23. The substrate processing method of claim 15,
wherein the processing of the substrate with the electroless plating liquid is performed while covering the substrate held on the rotary table with a top plate and supplying an inert gas to a space between the top plate and the substrate from a nozzle provided at the top plate.

24. The substrate processing method of claim 15, further comprising:
cleaning, after the holding of the substrate, a front surface of the substrate with a pre-cleaning liquid by supplying the pre-cleaning liquid onto the substrate while rotating the rotary table in a state where the power receiving electrode is separated from the power feeding electrode; and
removing, after the cleaning of the front surface of the substrate with the pre-cleaning liquid, the pre-cleaning liquid on the substrate with a rinse liquid,
wherein the forming of the puddle of the electroless plating liquid is performed after the removing of the pre-cleaning liquid.

25. The substrate processing method of claim 17, further comprising:
cooling, before the cleaning of the front surface of the substrate with the post-cleaning liquid, the rotary table,
wherein the rotary table has an attraction plate, and the substrate is attracted to a top surface of the attraction plate to be held by the rotary table, and
the cooling of the rotary table is performed by suctioning an atmosphere around the attraction plate from a suction hole formed in a surface of the attraction plate in a state where the attracting of the substrate to the attraction plate is released and the substrate is lifted by lift pins.

26. The substrate processing method of claim 15,
wherein the processing of the substrate with the electroless plating liquid includes stirring the electroless plating liquid on the substrate by rotating the rotary table in a forward rotation direction and in a backward rotation direction within a predetermined angular range in a state where the power receiving electrode is separated from the power feeding electrode; and then heating the electroless plating liquid on the substrate by bringing the power receiving electrode and the power feeding electrode into contact with each other.

27. The substrate processing method of claim 15,
wherein the substrate processing apparatus further includes an auxiliary heater provided in the rotary table to be rotated along with the rotary table,
the auxiliary heater is configured to be fed with the power even when the rotary table is being continuously rotated in one direction, and
wherein the substrate processing method further includes feeding the power to the auxiliary heater to maintain a temperature of the rotary table for at least a part of a period during which the power receiving electrode is separated from the power feeding electrode.
